(19) United States
(12) Patent Application Publication
(10) Pub. No.: US 2025/0070709 A1
(43) Pub. Date: Feb. 27, 2025

(54) METHOD AND SYSTEM FOR LOW EMISSIVITY, COLOR NEUTRAL INSULATED GLASS UNITS WITH TRANSPARENT PHOTOVOLTAICS

(71) Applicant: Ubiquitous Energy, Inc., Redwood City, CA (US)

(72) Inventors: Miles C. Barr, Redwood City, CA (US); Matthew E. Sykes, Chicago, IL (US); John A. Love, Mountain View, CA (US); Richa Pandey, Sunnyvale, CA (US)

(73) Assignee: Ubiquitous Energy, Inc., Redwood City, CA (US)

(21) Appl. No.: 18/437,048

(22) Filed: Feb. 8, 2024

Related U.S. Application Data
(63) Continuation of application No. 17/490,460, filed on Sep. 30, 2021, now abandoned.
(60) Provisional application No. 63/086,923, filed on Oct. 2, 2020.

(51) Int. Cl. H02S 20/26; E06B 3/67; E06B 9/24; H01L 31/0468

(52) U.S. Cl. CPC H02S 20/26; E06B 3/6715; E06B 9/24; H01L 31/0468; E06B 2009/2476

(57) ABSTRACT

An insulated glass unit (IGU) characterized by a transmitted IGU color (a*_{IGU}; b*_{IGU}) includes a photovoltaic structure characterized by a first transmitted color (a*₁; b*₁) and a low emissivity structure characterized by a second transmitted color (a*₂; b*₂). The first transmitted color and the second transmitted color are complementary.

### CROSS-REFERENCE TO RELATED APPLICATION

This application is a continuation of U.S. patent application Ser. No. 17/490,460, filed Sep. 30, 2021, which claims priority to and the benefit of U.S. Provisional Patent Application No. 63/086,923, filed Oct. 2, 2020, the disclosures of which are hereby incorporated by reference in their entirety for all purposes.

### BACKGROUND OF THE INVENTION

Low-cost, visibly transparent or semitransparent organic photovoltaic (OPV) devices that can be integrated into window panes in homes, skyscrapers, automobiles, and the like, may be used to significantly increase the surface area for solar energy harvesting. For example, building-integrated photovoltaic technologies can be used to convert solar energy irradiated onto buildings into electrical energy that can be used or stored at the building or can be fed back to the power grid and to reduce heating of the building by solar energy. However, such photovoltaic technologies have not been widely used due to, for example, the cost, opacity, and aesthetic issues associated with traditional photovoltaic cells.

Thus, there is a need in the art for improved methods and systems related to photovoltaic technologies implemented in insulated glass units.

### SUMMARY OF THE INVENTION

This application relates generally to the field of photovoltaic materials and devices, and, more particularly, to insulated glass units combining a visibly transparent (or semitransparent) photovoltaic structure and a low emissivity structure to provide a color neutral insulated glass unit while also improving the solar heat gain coefficient as compared to the use of the visibly transparent (or semitransparent) photovoltaic structure alone. In some embodiments, the photovoltaic and low emissivity structures are formed on separate lites (i.e., pieces of glass) and combined during fabrication of the insulated glass unit. The low emissivity structure preferentially transmits and reflects light in predetermined portions of the visible spectrum to complement the transmission spectrum of the visibly transparent photovoltaic structure.

By combining a low emissivity coated glass lite with a photovoltaic coated glass lite in an insulated glass unit, the overall combined color is more color neutral than that of the individual photovoltaic coated glass lite. In some embodiments, the transmitted color of the insulated glass unit can have lower b* value than the individual photovoltaic coated glass lite. In other embodiments, the transmitted color of the insulated glass unit lies in a color box defined by an a* between −15 and 0 and b* between −3.5 and 7.5. Thus, by pairing a complementary low emissivity coated glass lite with a non-color-neutral photovoltaic coated glass lite having a color displaced from the center of the color space, a predetermined color characterizing the insulated glass unit and improved color neutrality can be achieved.

According to an embodiment of the present invention, an insulated glass unit (IGU) characterized by a transmitted IGU color (a*_{IGU}; b*_{IGU}) is provided. The IGU includes a photovoltaic structure characterized by a first transmitted color (a*₁; b*₁) and a low emissivity structure characterized by a second transmitted color (a*₂; b*₂). The first transmitted color and the second transmitted color are complementary. In various embodiments, b*1>0 and b*₂<0; a*1<0 and a*₂>0; b*1<0 and b*₂>0; or a*1>0 and a*2<0. In a particular embodiment,

$$\sqrt{{( {a}_{IGU}^{*} )}^{2} + {( {b}_{IGU}^{*} )}^{2}} < \sqrt{{( {a}_{1}^{*} )}^{2} + {( {b}_{1}^{*} )}^{2}} ;$$

$$and$$

$$\sqrt{{( {a}_{IGU}^{*} )}^{2} + {( {b}_{IGU}^{*} )}^{2}} < \sqrt{{( {a}_{2}^{*} )}^{2} + {( {b}_{2}^{*} )}^{2}} .$$

In a specific embodiment, the photovoltaic structure includes a photovoltaic coating disposed on a first lite and the low emissivity structure comprises a low emissivity coating disposed on a second lite. The photovoltaic coating can be disposed on a surface of the first lite facing toward the second lite and the low emissivity coating can be disposed on a surface of the second lite facing away from the first lite. The photovoltaic structure can be separated from the low emissivity structure by a gap. The insulated glass unit can also include a third lite separated from the low emissivity structure by a second gap. The photovoltaic coating can be disposed on a surface of the first lite facing toward the second lite and the low emissivity coating can be disposed on a surface of the second lite facing toward the first lite. The photovoltaic structure can be separated from the low emissivity structure by a gap. In an embodiment, the insulated glass unit additionally includes a third lite separated from the low emissivity structure by a second gap. The photovoltaic coating can be disposed on a surface of the first lite facing toward the second lite and the low emissivity coating can be disposed on a surface of the second lite facing toward the first lite and a glass lite can be disposed between the photovoltaic structure and the low emissivity structure. The photovoltaic structure can be separated from the glass lite by a gap. The glass lite can be separated from the low emissivity structure by a second gap.

According to an embodiment of the present invention, an insulated glass unit (IGU) is provided. The IGU includes a photovoltaic structure including a first lite and characterized by a first transmitted color (a*₁; b*₁), a second lite laminated to the photovoltaic structure, and a low emissivity structure separated from the second lite by a gap, including a third lite, and characterized by a second transmitted color (a*₂; b*₂). The first transmitted color and the second transmitted color are complementary.

In some embodiments, |a*_{IGU}|<|a*₁| or |a*_{IGU}|<|a*₂|. In other embodiments, |b*_{IGU}|<|b*₁| or |b*_{IGU}|<|b*₂|. As an example, \sqrt{(a*_{IGU})²+(b*_{IGU})²}<\sqrt{(a*₁)²+(b*₁)²}; and \sqrt{(a*_{IGU})²+(b*_{IGU})²}<\sqrt{(a*₂)²+(b*₂)²} or \sqrt{(a*_{IGU})²+(b*_{IGU})²}<{square root over ((a*₁)²+(b*₁)² or \sqrt{(a*_{IGU})²}+(b*_{IGU})²)}<\sqrt{(a*₂)²+(b*₂)²}. The IGU can be characterized by an average visible transmission (AVT) of greater than 40% or greater than 50%.

According to another embodiment, an insulated glass unit (IGU) is provided. The IGU includes a photovoltaic structure characterized by a first transmitted color (a*₁; b*₁) and a low emissivity structure characterized by a second transmitted color (a*₂; b*₂). The first transmitted color and the second transmitted color are complementary. The IGU also includes a glass lite separated from the low emissivity structure by a gap. The photovoltaic structure can be disposed on an outboard side of the IGU. The photovoltaic structure can include a first lite and a photovoltaic coating, the low emissivity structure can include a second lite and a low emissivity coating, and the photovoltaic coating can be laminated to the second lite.

In some embodiments, the photovoltaic structure includes a photovoltaic coating disposed on a surface of a first lite facing toward the glass lite and the low emissivity structure includes a low emissivity coating disposed on a surface of a second lite facing toward the glass lite. The IGU can be characterized by a transmitted color (a*_{IGU}; b*_{IGU}). As an example, |a*_{IGU}|<|a*₁| or |a*_{IGU}|<|a*₂|; or |b*_{IGU}|<b*₁| or |b*_{IGU}|<|b*₂|. In an embodiment, \sqrt{(a*_{IGU})²+(b*_{IGU})²}<\sqrt{(a*₁)²+(b*₁)²} and \sqrt{(a*_{IGU})²+(b*_{IGU})²}<\sqrt{(a*₂)²+(b*₂)²} or \sqrt{(a*_{IGU})²+(b*_{IGU})²}<\sqrt{(a*₁)²+(b*₁)²} or \sqrt{(a*_{IGU})²+(b*_{IGU})²}<\sqrt{(a*₂)²+(b*₂)²}. In some embodiments, −4<b*_{IGU}<8 and/or b*₁ is positive and b*₂ is negative. The IGU can be characterized by an average visible transmission (AVT) of greater than 40%, for example, greater than 50%.

Numerous benefits are achieved using techniques described in the present disclosure over conventional techniques. For example, embodiments of the present invention provide insulated glass units that include a photovoltaic structure having a color unsuitable for most applications and a complementary low emissivity structure that, if integrated into the insulated glass unit in the absence of the photovoltaic structure, would also have a color unsuitable for most applications. Because of the complementary nature of the photovoltaic structure and low emissivity structure, the insulated glass unit is color neutral and suitable for a wide variety of applications. Additionally, the insulated glass units described herein are also characterized by an improved solar heat gain coefficient. Moreover, embodiments allow for the use of combinations of materials that might not otherwise be usable in photovoltaics due to color characteristics. Embodiments of the present invention utilize separate photovoltaic and low emissivity structures, allowing the use of less complex photovoltaic structures, and optionally less complex low emissivity structures. Furthermore, embodiments of the present invention utilize color tuning in the low emissivity structure, which is more easily accomplished than color tuning in the photovoltaic structure, achieved, for example, by changing the materials present in the photovoltaic structure. Additionally, multiple color targets could be identified for different products/markets, but these products could utilize the same photovoltaic structure or the same low emissivity structure. These and other embodiments of the disclosure, along with many of its advantages and features, are described in more detail in conjunction with the text below and corresponding figures.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a simplified schematic diagram illustrating an example of a visibly transparent photovoltaic device.

FIG. 2 is a simplified plot illustrating the solar spectrum, human eye sensitivity, and the absorption spectrum of an example of a transparent photovoltaic device as a function of light wavelength.

FIG. 3 illustrates the International Commission on Illumination (CIE) L*a*b* (CIELAB) color space for describing colors.

FIG. 4A is a simplified schematic diagram illustrating layers in a low emissivity structure according to an embodiment of the present invention.

FIG. 4B is a CIELAB color space illustrating the color of a number of low emissivity structures.

FIG. 5A is a simplified schematic diagram illustrating an insulated glass unit incorporating a photovoltaic structure and a low emissivity structure according to an embodiment of the present invention.

FIG. 5B is a CIELAB color space illustrating the colors of a photovoltaic structure, a low emissivity structure, and an IGU including the photovoltaic and low emissivity structures according to an embodiment of the present invention.

FIG. 6A is a simplified schematic diagram illustrating an insulated glass unit incorporating a photovoltaic coating, a low emissivity coating, and a glass lite according to an embodiment of the present invention.

FIG. 6B is a simplified schematic diagram illustrating an insulated glass unit incorporating a photovoltaic coating, a low emissivity coating, and a glass lite according to an alternative embodiment of the present invention.

FIG. 6C is a simplified schematic diagram illustrating an insulated glass unit incorporating a photovoltaic coating, a low emissivity coating, and a glass lite according to another alternative embodiment of the present invention.

FIG. 7A is a simplified schematic diagram illustrating a laminated insulated glass unit incorporating a photovoltaic coating, a low emissivity coating, and a glass lite according to an embodiment of the present invention.

FIG. 7B is a simplified schematic diagram illustrating a laminated insulated glass unit incorporating a photovoltaic coating, a low emissivity coating, and a glass lite according to an alternative embodiment of the present invention.

FIG. 7C is a simplified schematic diagram illustrating a laminated insulated glass unit incorporating a photovoltaic coating, a low emissivity coating, and a glass lite according to another alternative embodiment of the present invention.

FIG. 8A illustrates a plot of transmission vs. wavelength for a photovoltaic structure that preferentially transmits red light and a low emissivity structure that preferentially transmits blue light.

FIG. 8B illustrates a plot of transmission vs. wavelength for a photovoltaic structure that preferentially transmits blue light and a low emissivity structure that preferentially transmits red light.

FIG. 8C illustrates a plot of transmission vs. wavelength for a photovoltaic structure that preferentially transmits red and blue light and a low emissivity structure that preferentially transmits green light.

FIG. 8D illustrates a plot of transmission vs. wavelength for a photovoltaic structure that preferentially transmits green light and a low emissivity structure that preferentially transmits red and blue light.

FIG. 9A is a plot illustrating simulated optical properties of a photovoltaic structure according to a first embodiment of the present invention.

FIG. 9B is a plot illustrating simulated optical properties of a low emissivity structure according to the first embodiment of the present invention.

FIG. 9C is a simplified schematic diagram illustrating layers in the low emissivity structure having the optical properties shown in FIG. 9B.

FIG. 9D is a plot illustrating simulated optical properties of an IGU structure shown in FIG. 5A incorporating the photovoltaic structure having the optical properties shown in FIG. 9A and the low emissivity structure having the optical properties shown in FIG. 9B.

FIG. 9E is a CIELAB color space illustrating the color of the photovoltaic structure having the optical properties shown in FIG. 9A, the low emissivity structure having the optical properties shown in FIG. 9B, and the IGU having the optical properties shown in FIG. 9D.

FIG. 10A is a plot illustrating simulated optical properties of a photovoltaic structure according to a first alternative embodiment of the present invention.

FIG. 10B is a plot illustrating simulated optical properties of a low emissivity structure according to the first alternative embodiment of the present invention.

FIG. 10C is a simplified schematic diagram illustrating layers in the low emissivity structure having the optical properties shown in FIG. 10B.

FIG. 10D is a plot illustrating simulated optical properties of an IGU incorporating the photovoltaic structure having the optical properties shown in FIG. 10A and the low emissivity structure having the optical properties shown in FIG. 10B.

FIG. 10E is a CIELAB color space illustrating the color of the photovoltaic structure having the optical properties shown in FIG. 10A, the low emissivity structure having the optical properties shown in FIG. 10B, and the IGU having the optical properties shown in FIG. 10D.

FIG. 11A is a plot illustrating simulated optical properties of a photovoltaic structure according to a second embodiment of the present invention.

FIG. 11B is a plot illustrating simulated optical properties of a low emissivity structure according to the second embodiment of the present invention.

FIG. 11C is a simplified schematic diagram illustrating layers in the low emissivity structure having the optical properties shown in FIG. 11B.

FIG. 11D is a plot illustrating simulated optical properties of an IGU incorporating the photovoltaic structure having the optical properties shown in FIG. 11A and the low emissivity structure having the optical properties shown in FIG. 11B.

FIG. 11E is a CIELAB color space illustrating the color of the photovoltaic structure having the optical properties shown in FIG. 11A, the low emissivity structure having the optical properties shown in FIG. 11B, and the IGU having the optical properties shown in FIG. 11D.

FIG. 12A is a plot illustrating simulated optical properties of a photovoltaic structure according to a third embodiment of the present invention.

FIG. 12B is a plot illustrating simulated optical properties of a low emissivity structure according to the third embodiment of the present invention.

FIG. 12C is a simplified schematic diagram illustrating layers in the low emissivity structure having the optical properties shown in FIG. 12B.

FIG. 12D is a plot illustrating simulated optical properties of an IGU incorporating the photovoltaic structure having the optical properties shown in FIG. 12A and the low emissivity structure having the optical properties shown in FIG. 12B.

FIG. 12E is a CIELAB color space illustrating the color of the photovoltaic structure having the optical properties shown in FIG. 12A, the low emissivity structure having the optical properties shown in FIG. 12B, and the IGU having the optical properties shown in FIG. 12D.

FIG. 13A is a plot illustrating simulated optical properties of a photovoltaic structure according to a fourth embodiment of the present invention.

FIG. 13B is a plot illustrating simulated optical properties of a low emissivity structure according to the fourth embodiment of the present invention.

FIG. 13C is a simplified schematic diagram illustrating layers in the low emissivity structure having the optical properties shown in FIG. 13B.

FIG. 13D is a plot illustrating simulated optical properties of an IGU incorporating the photovoltaic structure having the optical properties shown in FIG. 13A and the low emissivity structure having the optical properties shown in FIG. 13B.

FIG. 13E is a CIELAB color space illustrating the color of the photovoltaic structure having the optical properties shown in FIG. 13A, the low emissivity structure having the optical properties shown in FIG. 13B, and the IGU having the optical properties shown in FIG. 13D.

The figures depict embodiments of the present disclosure for purposes of illustration only. For example, the transmission or absorption curves in some figures are for illustration purposes only and may not represent the transmission or absorption curve of a material used in an actual transparent photovoltaic device. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF SPECIFIC EMBODIMENTS

The present disclosure relates generally to photovoltaic materials and devices, such as transparent or semitransparent photovoltaic materials and devices. More particularly, and without limitation, disclosed herein are insulated glass units that combine a visibly transparent (or semitransparent) photovoltaic structure with a low emissivity structure such that the insulated glass unit is characterized by a predetermined transmitted color. In a specific embodiment, the light transmitted by the insulated glass unit is closer to the center of the color space (i.e., more color neutral) than light transmitted by the photovoltaic structure. As described herein, the color characteristics of the photovoltaic structure and the low emissivity structure can be complementary such that an insulated glass unit including both the photovoltaic structure and the low emissivity structure transmits light with a color closer to the center of the CIELAB color space than the color of either the photovoltaic structure or the low emissivity structure.

Traditional photovoltaic devices, such as crystalline silicon photovoltaic devices, are generally opaque to visible light, and thus may not be suitable for use in window panes of buildings or other structures. Some transparent photovoltaic devices, such as some organic transparent photoactive material-based transparent photovoltaic devices, may be transparent or semitransparent to visible light. However, these transparent photovoltaic devices may have a structured absorption (or transmission) spectra in the visible band, and thus may show certain colors, such as certain shades of magenta, yellow, green, or blue, and may change the color or colors of the objects viewed by a person through the transparent photovoltaic devices.

According to embodiments of the present invention, various combinations of transparent or semitransparent photovoltaic structures and low emissivity structures are utilized in an insulated glass unit to achieve a predetermined color characteristic. Utilizing the methods and systems described herein, the transmission spectra of the insulated glass unit can be tailored to meet design constraints while also providing energy efficiency benefits. Thus, embodiments of the present invention provide insulated glass units that have the ability to generate electricity from incident solar radiation via a photovoltaic device, while still allowing visible light to pass through the insulated glass unit with a color (i.e., in transmission) that is consistent with conventional insulated glass unit products.

As used herein, the term “visible light” may refer to light within a wavelength range from about 380 nm to about 750 nm, from about 400 nm to about 700 nm, or from about 450 nm to about 650 nm.

As used herein, the terms “visibly transparent” (or simply “transparent”) and “visibly semitransparent” (or simply “semitransparent”), and the like, may refer to a character of a material or device that exhibits an overall absorption, average absorption, or maximum absorption in the visible band within about 0%-70%, such as less than or about 70%, less than or about 65%, less than or about 60%, less than or about 55%, less than or about 50%, less than or about 45%, less than or about 40%, less than or about 35%, less than or about 30%, less than or about 25%, or less than or about 20%. Stated another way, visibly transparent materials may transmit 30%-100% of incident visible light, such as greater than or about 80% of incident visible light, greater than or about 75% of incident visible light, greater than or about 70% of incident visible light, greater than or about 65% of incident visible light, greater than or about 60% of incident visible light, greater than or about 55% of incident visible light, greater than or about 50% of incident visible light, greater than or about 45% of incident visible light, greater than or about 40% of incident visible light, greater than or about 35% of incident visible light, or greater than or about 30% of incident visible light. Some of the light not transmitted through the material or device may be scattered, reflected, or absorbed by the materials. Visibly transparent materials are generally considered at least partially see-through (i.e., not completely opaque) when viewed by a human. A visibly transparent photovoltaic device may be simply referred to as a transparent photovoltaic (TPV) device.

As used herein, the term “average visible transmission” (commonly denoted as AVT or Tvis) refers to an average transmission over the wavelength spectrum weighted by the photopic response of the human eye, which is sensitive in the visible part of the spectrum.

As used herein, the term “complementary colors” may refer to colors associated with components of an IGU, which, when illuminated by white light (including a combination of light in different colors), transmit light for which the CIELAB a* and b* values span the corresponding CIELAB a* or b* value of the IGU. In other words, the components of an IGU may have complementary colors if, when illuminated by white light, the light transmitted by the IGU has a CIELAB a* value or a CIELAB b* value between the corresponding a* or b* values of the photovoltaic structure and the low emissivity structure. If, for example, the b* value of the photovoltaic structure is positive and the b* value of the low emissivity structure is negative, then an IGU incorporating these components with complementary colors would have a b* value between the negative b* value and the positive b* value, which span or are astride the b* value of the IGU, resulting in an IGU with a b* value closer to b*=0 than either the negative or positive b* values. Thus, as described herein, using components with complementary colors, color neutral IGUs can be fabricated, even in some embodiments where neither component lite is color neutral on its own.

As used herein, the term “color neutral” or “visibly color neutral” may refer to a color associated with an IGU or lite, which, when illuminated by white light (including a combination of light in different colors), transmits light for which the CIELAB a* and b* values are within a predetermined distance from the center (i.e., a*=0, b*=0) of the color space. In one embodiment, color neutral is defined as the IGU color being in a range of −5<a*<5, −5<b*<5, i.e., inside a color region of length ten and width ten centered at the center of the color space. In other embodiments, the range for the a* or b* values can vary depending on the particular application. Using components with complementary colors, the color of the IGU can be more color neutral, i.e., closer to the center region of the color space, than the color of either of the components (e.g., a photovoltaic structure and a low emissivity structure) that are integrated into the IGU. Thus, as an example, an IGU may be more color neutral than the components if, when illuminated by white light, the light transmitted by the IGU has a CIELAB a* value or a CIELAB b* value lower in magnitude than the a* or b* values of the photovoltaic structure or the low emissivity structure. In some embodiments, the IGU can be considered to be more color neutral than the components (e.g., photovoltaic structure and low emissivity structure) if, when illuminated by white light, the IGU transmits light having a color for which the distance from the center of the color space to the color associated with the IGU is less than the distance from the center of the color space to one or more (e.g., both) of the colors associated with the components.

Although some of the examples illustrated herein and the discussion associated with these examples are provided in the context of high transparency photovoltaic coatings, for example, photovoltaic coatings that have a transmission of >30% or >50% and UV or NIR absorption peaks, embodiments of the present invention are not limited to these particular photovoltaic coatings. More generally, embodiments of the present invention are applicable to IGUs that include photovoltaic and low emissivity structures that include photovoltaic coatings that have lower transparency, for instance, a photovoltaic coating with a transmission greater than 0% can be color neutralized using the methods and systems described herein. Accordingly, IGUs that are characterized by an AVT of 5%, 10%, 20%, and 30% can be fabricated using the methods and systems described herein and would have substantial market applicability. Moreover, photovoltaic coatings that are not selective in the NIR (e.g., visibly absorbing, but semi-transparent) can also be utilized. Example photovoltaic coatings are discussed in commonly assigned U.S. Patent Application Publication Nos. 2019/0036480 and 2020/0091355, the disclosures of which are hereby incorporated by reference in their entirety for all purposes. Examples include photovoltaics based on semitransparent perovskites, cadmium telluride, silicon, gallium arsenide, copper indium gallium selenide, ITIC style organic photovoltaics, or the like, including photovoltaics that are not designed to be NIR selective, all of which would benefit from color neutralization via pairing with low emissivity structures as described herein.

In addition, although some of the examples illustrated herein and the discussion associated with these examples are provided in the context of photovoltaic coatings, the methods and systems described herein are also applicable to color neutralization of luminescent solar concentrators. Additional description related to luminescent solar concentrators is provided in U.S. Patent Application Publication No. 2018/0248064 and commonly assigned U.S. Patent Application Publication No. 2019/0036480, the disclosures of which are hereby incorporated by reference in their entirety for all purposes.

As used herein, the term “maximum absorption strength” refers to the largest absorption value in a particular spectral region, such as the ultraviolet band (200 nm to 450 nm or 280 nm to 450 nm), the visible band (450 nm to 650 nm), or the near-infrared band (650 nm to 1400 nm). In some examples, a maximum absorption strength may correspond to an absorption strength of an absorption feature that is a local or absolute maximum, such as an absorption band or peak, and may be referred to as a peak absorption. In some examples, a maximum absorption strength in a particular band may not correspond to a local or absolute maximum, but may instead correspond to the largest absorption value in the particular band. Such a configuration may occur, for example, when an absorption feature spans multiple bands (e.g., visible and near-infrared), and the absorption values from the absorption feature that occur within the visible band are smaller than those occurring within the near-infrared band, such as when the peak of the absorption feature is located within the ultraviolet band but a tail of the absorption feature extends to the visible band. In some embodiments, a visibly transparent photoactive compound described herein may have an absorption peak at a wavelength greater than about 650 nanometers (i.e., in the near-infrared) or at a wavelength less than about 450 nanometers (i.e., in the ultraviolet), and the visibly transparent photoactive material's absorption peak may be greater than the visibly transparent photoactive material's absorption at any wavelength between about 450 and 650 nanometers.

In the following description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

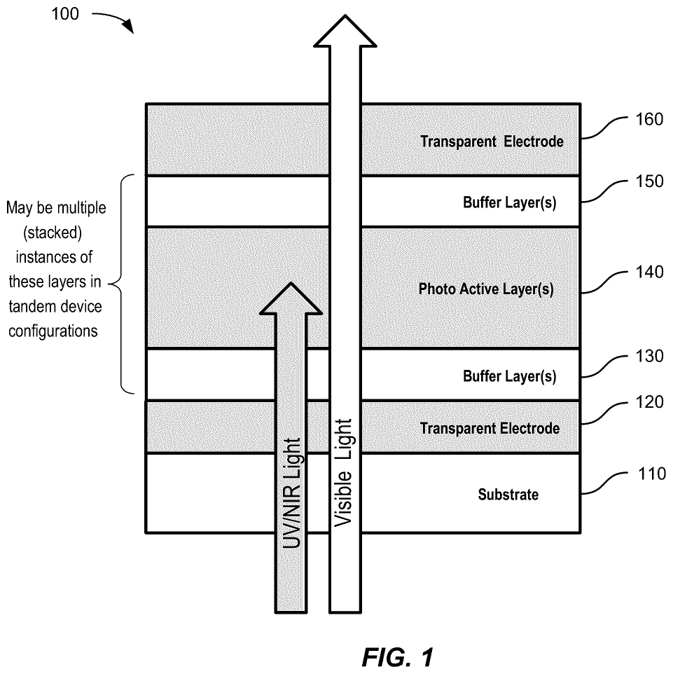

FIG. 1 is a simplified diagram illustrating an example of a visibly transparent photovoltaic (TPV) structure 100 that can be utilized in the IGUs described herein. As illustrated in FIG. 1, visibly transparent photovoltaic structure 100 may include a number of layers and elements. As described above, visibly transparent indicates that the photovoltaic device absorbs optical energy at wavelengths outside the visible wavelength band of, for example, about 450 nm to about 650 nm, while substantially transmitting light inside the visible wavelength band. As illustrated in the example, UV and/or NIR light may be strongly absorbed by the layers and elements of the transparent photovoltaic device while visible light may be substantially transmitted through the device.

Visibly transparent photovoltaic structure 100 may include a substrate 110, which can be glass or other visibly transparent materials providing sufficient mechanical support to the other layers and structures illustrated. Example substrate materials include various glasses and rigid or flexible polymers. Multilayer substrates, such as laminates, may also be utilized. Substrates may have any suitable thickness to provide the mechanical support needed for the other layers and structures, such as, for example, thicknesses from 0.5 mm to 20 mm. In some cases, the substrate may include an adhesive film to allow application of the visibly transparent photovoltaic structure 100 to another structure, such as a window pane, display device, and the like.

Visibly transparent photovoltaic structure 100 may include a set of transparent electrodes 120 and 160 with a photoactive layer 140 positioned between transparent electrodes 120 and 160. Transparent electrodes 120 and 160, which can be fabricated using ITO, thin metal films, or other suitable visibly transparent materials, provide electrical connection to one or more of the various layers illustrated. For example, thin films of copper, silver, or other metals may be suitable for use as a visibly transparent electrode, even though these metals may absorb light in the visible band. When provided as a thin film, such as a film having a thickness about 1 nm to about 200 nm (e.g., about 5 nm, about 10 nm, about 15 nm, about 20 nm, about 25 nm, about 30 nm, about 35 nm, about 40 nm, about 45 nm, about 50 nm, about 55 nm, about 60 nm, about 65 nm, about 70 nm, about 75 nm, about 80 nm, about 85 nm, about 90 nm, about 95 nm, about 100 nm, about 105 nm, about 110 nm, about 115 nm, about 120 nm, about 125 nm, about 130 nm, about 135 nm, about 140 nm, about 145 nm, about 150 nm, about 155 nm, about 160 nm, about 165 nm, about 170 nm, about 175 nm, about 180 nm, about 185 nm, about 190 nm, or about 195 nm), an overall transmittance of the thin film in the visible band may remain high, such as greater than 30%, greater than 40%, greater than 50%, greater than 60%, greater than 70%, greater than 80%, or greater than 90%. Advantageously, thin metal films, when used as transparent electrodes, may exhibit lower absorption in the ultraviolet band than some semiconducting materials that may be useful as a transparent electrode, such as ITO, as some semiconducting transparent conducting oxides may have a band gap in the ultraviolet band and thus may be highly absorbing or opaque to ultraviolet light. In some cases, however, an ultraviolet absorbing transparent electrode may be used, such as to screen at least a portion of the ultraviolet light from underlying components, because ultraviolet light may degrade certain materials.

A variety of deposition techniques may be used to generate a transparent electrode, including vacuum deposition techniques, such as atomic layer deposition, chemical vapor deposition, physical vapor deposition, thermal evaporation, sputter deposition, epitaxy, and the like. Solution based deposition techniques, such as spin-coating, may also be used in some cases. In addition, transparent electrodes may be patterned using techniques for microfabrication, including lithography, lift off, etching, and the like.

Buffer layers 130 and 150 and photoactive layer 140 are utilized to achieve the electrical and optical properties of the photovoltaic device. These layers can be layers of a single material or can include multiple sub-layers as appropriate for the particular application. Thus, the term “layer” is not intended to denote a single layer of a single material, but can include multiple sub-layers of the same or different materials. In some embodiments, buffer layer 130, photoactive layer(s) 140, and buffer layer 150 are repeated in a stacked configuration to provide tandem device configurations, such as multi-junction cells. In some embodiments, photoactive layer(s) 140 may include electron donor materials and electron acceptor materials, also referred to as donors and acceptors. These donors and acceptors are visibly transparent, but may absorb outside the visible wavelength band to generate photocurrent.

Buffer layers 130 and 150 may function as electron transport layers, electron blocking layers, hole transport layers, hole blocking layers, exciton blocking layers, optical spacers, physical buffer layers, charge recombination layers, charge generation layers, or the like. Buffer layers 130 and 150 may have any suitable thickness to provide the buffer effect desired and may optionally be present or absent. Buffer layers 130 and 150, when present, may have thicknesses from about 1 nm to about 100 nm. Additionally, buffer layers 130 and 150 may have absorption complementary to photoactive layers in some embodiments. Various materials may be used as buffer layers, including fullerene materials, carbon nanotube materials, graphene materials, metal oxides, such as molybdenum oxide, titanium oxide, zinc oxide, and the like; polymers, such as poly(3,4-ethylenedioxythiophene), polystyrene sulfonic acid, polyaniline, and the like; copolymers, polymer mixtures, and small molecules, such as bathocuproine. Buffer layers may be formed using a deposition process (e.g., thermal evaporation) or a solution processing method (e.g., spin coating), and may include one or more layers.

It is noted that, in various embodiments, visibly transparent photovoltaic structure 100 may include transparent electrode 120, photoactive layer 140, and transparent electrode 160, while any one or more of substrate 110, and buffer layers 130 and 150 may be optionally included or excluded.

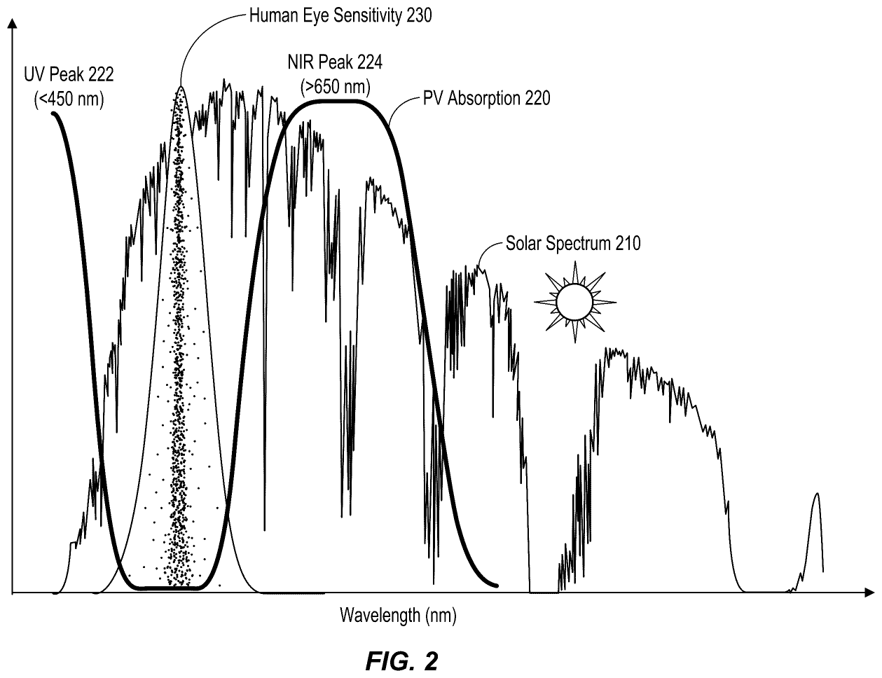

FIG. 2 is a simplified plot illustrating the solar spectrum 210, human eye sensitivity 230, and the absorption spectrum 220 of an example of a transparent photovoltaic structure as a function of light wavelength. As illustrated in FIG. 2, embodiments of the present invention utilize photovoltaic structures that have low absorption in the visible wavelength band between about 450 nm and about 650 nm, but strongly absorb in the UV and NIR bands, i.e., outside the visible wavelength band, enabling visibly transparent photovoltaic operation. As described more fully herein, for cases where the absorption is not uniform, color neutralization is utilized to compensate for the non-uniform absorption. The ultraviolet band may be described, in embodiments, as wavelengths of light between about 200 nm and about 450 nm. It will be appreciated that useful solar radiation at ground level may have limited amounts of ultraviolet light with wavelengths less than about 280 nm, and thus, in some embodiments, the ultraviolet band or ultraviolet region may be described as wavelengths of light between about 280 nm and 450 nm. The near-infrared band may be described, in embodiments, as wavelengths of light of between about 650 nm and about 1400 nm. Various structures described herein may exhibit absorption including a UV peak 222 and/or a NIR peak 224, and a maximum absorption strength in the visible band smaller than that in the NIR region or UV region.

TPV devices fabricated using photoactive materials that absorb light in the UV and/or NIR band of solar spectrum may absorb primarily in the UV and/or NIR band, and may also have absorption that extends from the UV or NIR band into the visible band of the solar spectrum. As a result, the TPV materials or structure may show a certain color due to the non-uniform visible light absorption. As described above, it is often desirable to achieve a predetermined color for the IGU, for example, a neutral color or a color with a blue-green tint, such that the IGU is suitable for a particular architectural style, provides a color desired by the owner, or the like.

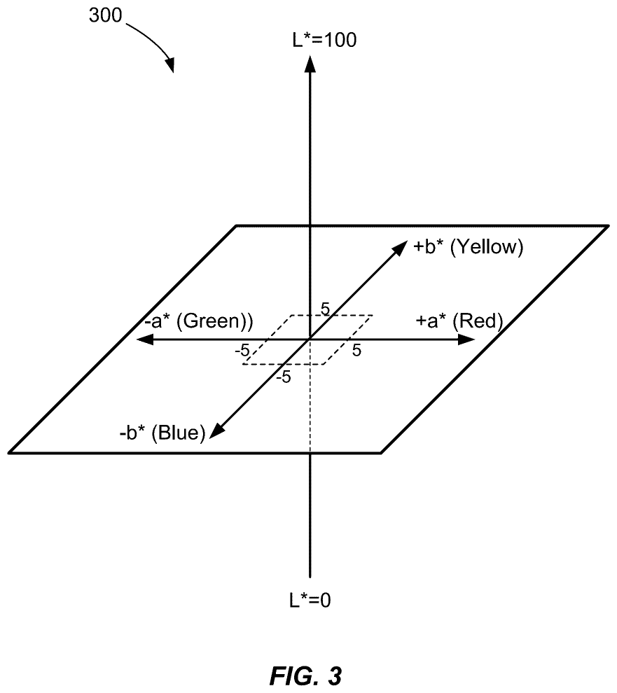

FIG. 3 illustrates the CIELAB color space for describing colors. The CIE L*a*b* (CIELAB) color space 300 describes colors visible to human eyes and is a device-independent model. The three coordinates of the CIELAB color space represent the lightness of a color, the position of the color between red/magenta and green, and the position of the color between yellow and blue. CIELAB is designed such that the same amount of numerical change in CIELAB values corresponds to approximately the same amount of visually perceived change. Unlike the RGB and CMYK color models, CIELAB color space is designed to approximate human vision.

As shown in FIG. 3, the three coordinates of the CIELAB color space are L*, a*, and b*, where the “*” is used to distinguish L*, a*, and b* from Hunter's L, a, and b. Lightness value L* represents the brightness of a color, ranging from the darkest black at L*=0 to the brightest white at L*=100. The a* axis represents the green-red component, with green in the negative direction and red in the positive direction. The b* axis represents the blue-yellow component, with blue in the negative direction and yellow in the positive direction. True neutral gray colors are represented by a*=0 and b*=0. The scaling and limits of the a* and b* axes may depend on the specific implementation. For example, in some implementations, a* and b* values may be in the range of ±100 or −128 to +127 (signed 8-bit integer). The nonlinear relations for L*, a*, and b* are intended to mimic the nonlinear response of the eye.

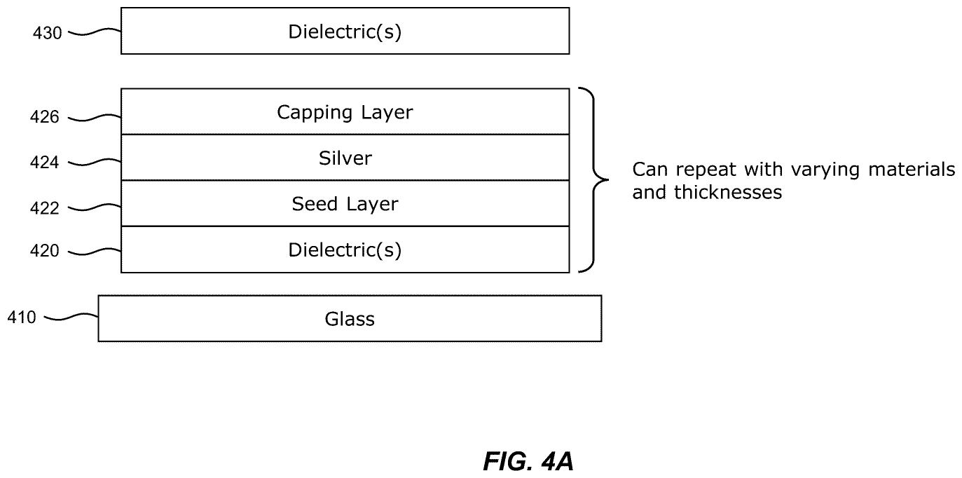

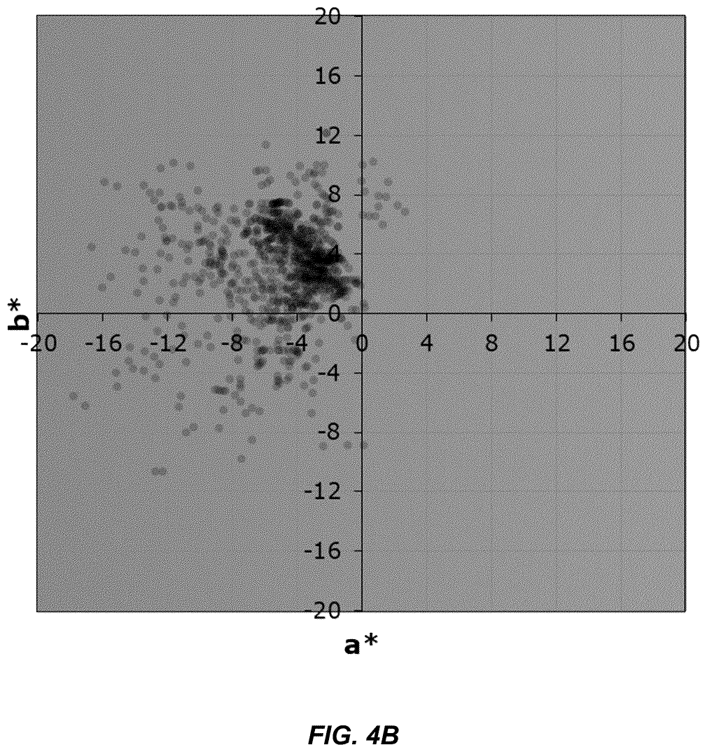

In some embodiments, the a* and b* values of white light after transmission through a color neutral IGU may be within, for example, between −5 and 5, between −10 and 10, or in a particular quadrant (e.g., quadrant III, where a* and b* are both negative) in the a*-b* plane shown in FIG. 3, such that the color of the IGU or the resultant color of the white light transmitted through the IGU is close to a white or gray color. As described herein with respect to FIGS. 4A and 4B, conventional low emissivity glasses generally have a transmitted color with CIELAB values of −15<a*<0; −7<b*<8.

The term “color box” used herein defines a rectangular region of color space. As discussed above, in IGU applications, there is no specific color box that is generally ascribed to “color neutral” or “non-color-neutral,” although it is possible to set bounds for such a description. Describing the process of color neutralization can be implemented numerically and be described as having an IGU with a color closer to the origin of the color space than the colors of the various components making up the IGU. Thus, in this definition, if the IGU color is (a_{IGU}*; b_{IGU}*), the color of the photovoltaic structure is (a₁*; b₁*), and the color of the low emissivity structure is (a₂*; b₂*), the IGU color is color neutral with respect to the first color and the second color if

$$\sqrt{{( {a}_{IGU}^{*} )}^{2} + {( {b}_{IGU}^{*} )}^{2}} < \sqrt{{( {a}_{1}^{*} )}^{2} + {( {b}_{1}^{*} )}^{2}} ;$$

$$and$$

$$\sqrt{{( {a}_{IGU}^{*} )}^{2} + {( {b}_{IGU}^{*} )}^{2}} < \sqrt{{( {a}_{2}^{*} )}^{2} + {( {b}_{2}^{*} )}^{2}} .$$

In an alternative embodiment, the description of the process of color neutralization can be implemented numerically and be described as having an IGU with a color closer to the origin of the color space than at least one of the components making up the IGU. Thus, in this definition, if the IGU color is (a_{IGU}*; b_{IGU}*), the color of the photovoltaic structure is (a₁*; b₁*), and the color of the low emissivity structure is (a₂*; b₂*), the IGU color is color neutral with respect to the first color or the second color if

$$\sqrt{{( {a}_{IGU}^{*} )}^{2} + {( {b}_{IGU}^{*} )}^{2}} < \sqrt{{( {a}_{1}^{*} )}^{2} + {( {b}_{1}^{*} )}^{2}} ;$$

$$or$$

$$\sqrt{{( {a}_{IGU}^{*} )}^{2} + {( {b}_{IGU}^{*} )}^{2}} < \sqrt{{( {a}_{2}^{*} )}^{2} + {( {b}_{2}^{*} )}^{2}} .$$

As will be evident to one of skill in the art, low emissivity structures have been utilized in windows to increase the energy efficiency of windows. A low emissivity structure reduces the emission of radiant infrared energy, thus keeping the heat on the side of the glass where it originated, while letting visible light pass. In other words, low emissivity structures transmit visible light while not transmitting IR light. This results in a window with better energy efficiency: heat originating from indoors in winter remains inside (the warm side), while heat during summer does not transmit through the window, keeping it cooler inside.

FIG. 4A is a simplified schematic diagram illustrating layers in a low emissivity structure according to an embodiment of the present invention. Low emissivity refers to the condition that a material radiates low levels of thermal energy as compared to black body radiation. Low emissivity coatings are used in windows to reduce the amount of heat transmitted into and out of a building to reduce heating and cooling costs. They are designed to preferentially absorb or reflect infrared light while allowing the transmission of visible light. In implementation, low emissivity coatings reflect IR light incident on the coating while allowing visible wavelengths to pass through the coating. This reduces the amount of solar heat gained, improving the energy efficiency of the window.

Most low emissivity coatings are made with 1-4 layers of thin silver sandwiched between transparent dielectric layers such as oxides or nitrides. These layers can be deposited on a glass or other suitable substrate. Capping layers and seed layers can be used to help ensure the silver forms a continuous film and is stable over time. The optical cavities formed by the various layers allow for the tuning of the reflection and transmission spectra by adjusting the thicknesses of the dielectric layers. Moreover, different dielectric materials have different indices of refraction, and thus, using multiple dielectric materials provides even more control over the optical properties of the low emissivity structure.

Although FIG. 4A illustrates a low emissivity structure including a glass substrate 410, one or more dielectric layer(s) 420, seed layer 422, silver layer 424, capping layer 426, which may be a dielectric material, and one or more dielectric layer(s) 430, embodiments of the present invention are not limited to this particular low emissivity structure and other structures that provide the functionality of low emissivity coatings, particularly low transmission in the IR coupled with high transmission in the visible, are included within the scope of the present invention.

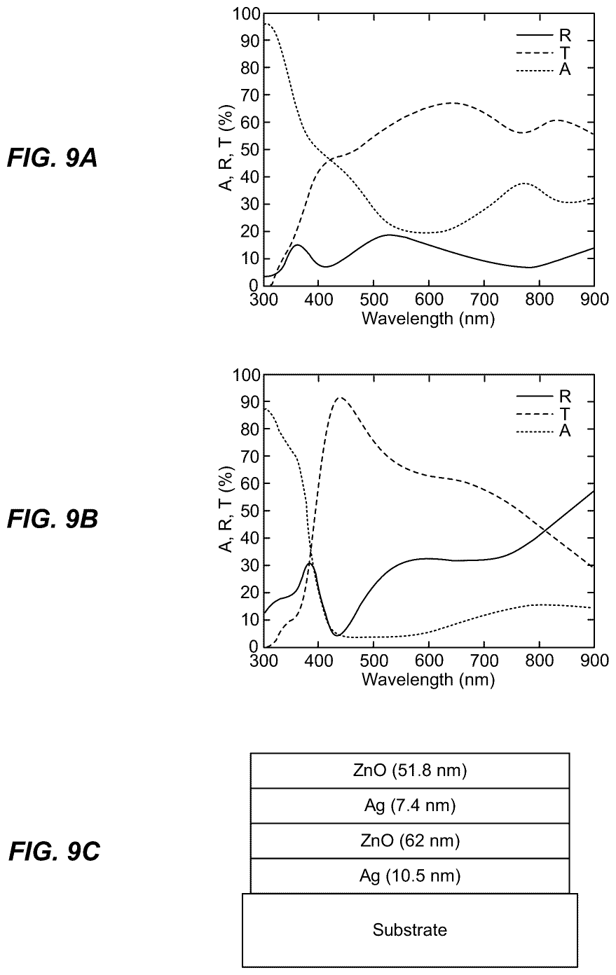

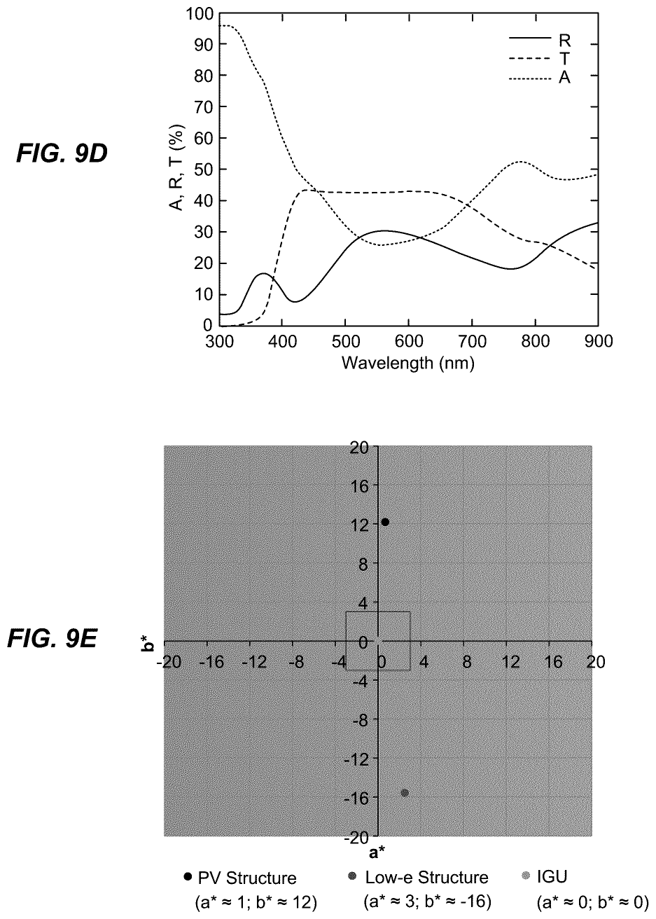

The low emissivity stacks illustrated in FIGS. 9C, 10C, 11C, 12C, and 13C all utilize a relatively simple version of the structure illustrated in FIG. 4A and use a simple set of example materials for the purpose of simulation and demonstration of the applicability of embodiments of the present invention. In practice, additional layers can and would likely be used for manufacturability and stability. More complicated structures, utilizing additional silver layers or additional dielectric layers would afford even greater control over the transmission spectrum of a low emissivity coated glass lite. The dielectric materials used in the examples discussed herein should be considered as proxies for the large set of dielectrics currently used in the low emissivity glass industry that includes, but is not limited to, silicon oxides (SiOₓ), silicon nitrides (SiNₓ), tin oxides (SnOₓ), zinc oxides (ZnOx), zinc tin oxides (ZnSnOx), titanium oxides (TiOx), zinc titanium oxides (ZnTiOₓ), zinc aluminum oxides (ZnAlOₓ), and nickel chromium oxides (NiCrOₓ). The stoichiometry of the dielectrics can also be varied and not limited to the formulas shown. Likewise, in addition to silver, metals including, but not limited to, chromium (Cr), nickel chromium (NiCr), and titanium (Ti) are often used as capping layers in the low emissivity stacks. Substitution of these, or other materials into low emissivity structures of the type shown in FIG. 4A do not fundamentally change the aspects of embodiments of the present invention. The tunability of the color is a general property of these types of optical structures.

FIG. 4B is a CIELAB color space illustrating the color of a number of low emissivity structures. In FIG. 4B, all 970 glass products in the International Glazing Database classified as low emissivity (emissivity <0.1) and high transparency (Tᵥᵢₛ>0.4) are illustrated. Accordingly, this data set provides color information on IGUs for residential and commercial applications. As can be seen in FIG. 4B, the vast majority of products fall within a small range of colors (green, grey, and blue) and are relatively color neutral. For various reasons, including architectural style, there is not necessarily an “ideal” color. Rather, there is a range of acceptable transmission colors depending on the application and the eye of the beholder.

Examining the data in FIG. 4B, 90% of the glass products are contained within a color box defined by −15<a*<0; −4<b*<8, i.e., a green, blue, or grey tint as these are desirable colors for architectural reasons. 99% of the glass products are contained within a color box defined by −17<a*<3; −7<b*<11. Utilizing a radial color box, 90% of the glass products are contained within a circle having a radius of 7 centered at a*=−6, b*=3.3. Thus, the vast majority of windows for residential and commercial applications are characterized by a color having a blue-green tint (i.e., −15<a*<0; −4<b*<8).

Embodiments of the present invention provide methods and systems to integrate a photovoltaic structure into an IGU with a low emissivity structure, while still providing the blue-green tint associated with the color profile shown in FIG. 4B. Thus, embodiments are able to add low emissivity functionality in combination with a photovoltaic coating to improve energy efficiency while also generating power.

Since increased transparency is a desirable characteristic of TPV devices, conventional TPV design metrics result in migration of the color of the TPV to the region of the color space in which low emissivity coatings are located, i.e., a*≈−4, b*≈4. Physically, low emissivity coatings have this color because it aligns with the photopic response of the eye. Thus, designing a low emissivity structure and a photovoltaic structure in isolation, the color of the low emissivity structure and photovoltaic structure will tend to be located in color space in the region of a*≈−4, b*≈4 as illustrated in FIG. 4B. However, when combining a photovoltaic structure and low emissivity structure in an IGU, if both the photovoltaic structure and low emissivity structure have a color in the region of a*≈−4, b*≈4, the IGU will have a color that is shifted to lower a* values and higher b* values, thereby resulting in an IGU that has an undesirable color. Embodiments of the present invention address this problem by utilizing photovoltaic structures and low emissivity structures that are complementary, enabling the color of the IGU to be controlled in order to produce a color neutral IGU. Thus, although neither the photovoltaic structure or the low emissivity structure would have a desirable color in isolation, in combination, the complementary nature of the photovoltaic structure and low emissivity structure provide a desirable color for the IGU.

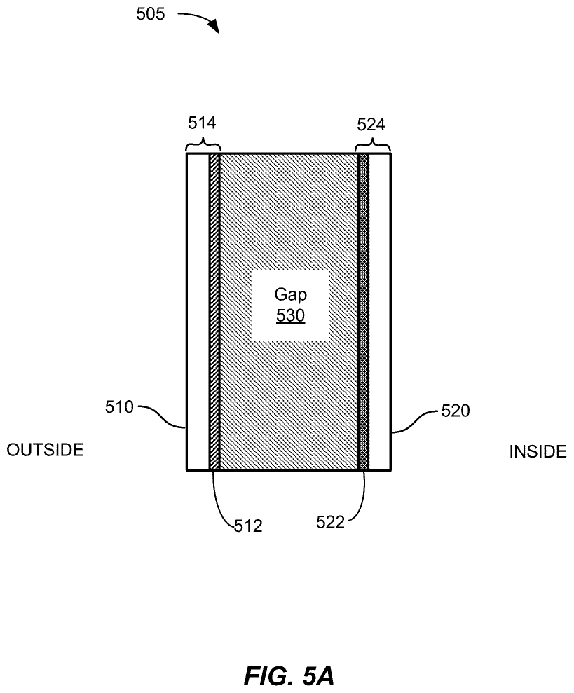

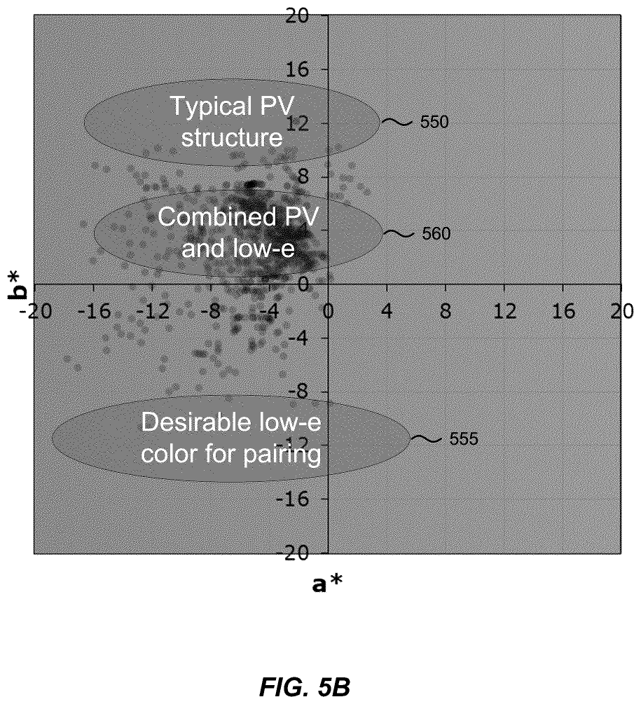

FIG. 5A is a simplified schematic diagram illustrating an insulated glass unit (IGU) incorporating a photovoltaic structure and a low emissivity structure according to an embodiment of the present invention. As illustrated in FIG. 5A, a first lite 510 (i.e., a first piece of glass) is coated with a photovoltaic coating 512 to form a photovoltaic structure 514. A second lite 520 (i.e., a second piece of glass) is coated with a low emissivity coating 522 to form a low emissivity structure 524. The photovoltaic structure 514 and the low emissivity structure 524 are then assembled with gap 530 separating photovoltaic structure 514 and low emissivity structure 524 form IGU 505. Gap 530 can be filled with vacuum, air, an inert gas such as argon, krypton, xenon, or another gas such as nitrogen, combinations thereof, or the like.

IGU 505 is typically installed such that solar radiation is incident on first lite 510, which faces the outside of the structure, and passes through IGU 505 toward the inside of the structure. Thus, in the construction shown in FIG. 5, photovoltaic coating 512 and low emissivity coating 522 are enclosed inside IGU 505 with photovoltaic coating 512 disposed on the outboard lite and low emissivity coating 522 disposed on the inboard lite.

In addition to dual pane constructions, some embodiments of the present invention can utilize triple plane constructions in the form of “triple IGUs” with three pieces of glass and the photovoltaic coating and the low emissivity coating on various surfaces. As described below, the different orientations may be more or less applicable depending on the climate in which the IGU is utilized. Additional description related to IGUs, including description related to particular spacers, busbars, wire connections, and the like, is provided in U.S. Patent Application Publication No. 2019/0036480.

As described in relation to FIG. 5B, the combination of photovoltaic structure 514 and low emissivity structure 524 as illustrated in FIG. 5A, results in a color neutral IGU that produces energy while also being characterized by an improved solar heat gain coefficient. The color of IGU 505 is determined by the visible transmission profile of the low emissivity structure in combination with that of the photovoltaic structure and can be tuned by changing the thickness or materials used in the low emissivity structure. Thus, utilizing the combination of photovoltaic structure 514 and low emissivity structure 524, the color of IGU 505 can be tailored to meet the particular application while achieving the energy efficiency associated with conventional low emissivity coatings.

FIG. 5B is a CIELAB color space illustrating the colors of a photovoltaic structure, a low emissivity structure, and an IGU including the photovoltaic and low emissivity structures according to an embodiment of the present invention. As illustrated in FIG. 5B, photovoltaic coatings are sometimes characterized by negative a* values and highly positive b* values. This color characteristic is illustrated by oval 550 in FIG. 5B. From a color perspective, if the IGU including the low emissivity structure were characterized by colors in oval 550, they would be unacceptable for most commercial and residential applications. Rather, as discussed in relation to FIG. 4B, most IGUs including low emissivity coatings are characterized by a color having a blue-green tint (i.e., −10<a*<0; 0<b*<5).

Given the color of the photovoltaic structure, embodiments of the present invention pair the photovoltaic structure with a low emissivity structure having a highly negative b* value to achieve an IGU color having a blue-green tint (i.e., −10<a*<0; 0<b*<5). Accordingly, as illustrated in FIG. 5B, low emissivity structures having a color characteristic illustrated by oval 555 are paired with photovoltaic structures having a color characteristic illustrated by oval 550 to achieve an IGU with a color in the vicinity of a*=−4; b*=4 illustrated by IGU oval 560. By pairing a low emissivity structure with a color that is a much deeper blue (i.e., a highly negative b* value) than the desired IGU color, the high b* value associated with the photovoltaic structure is neutralized to produce an IGU with a color positioned in the color space illustrated by IGU oval 560 positioned between the colors of the photovoltaic structure and low emissivity structure, respectively, thereby providing an IGU with a color associated with the vast majority of current products.

As discussed previously, the IGU can be considered to be color neutral if either the a* or b* value for the IGU is closer to the center of the color space than the a* and b* values corresponding to the colors associated with the photovoltaic structure and the low emissivity structure. As illustrated in FIG. 5B, the color of the photovoltaic structure has a b* value greater than about 8 and the color of the low emissivity structure has a b* value less than about −8. The IGU including such a photovoltaic structure and low emissivity structure would have a color having a b* value of about 4, which is color neutral with respect to the photovoltaic structure and the low emissivity structure because the b* value of the IGU is closer to the center of the color space than the b* value for either the photovoltaic structure or the low emissivity structure. Accordingly, the IGU is color neutral with respect to the photovoltaic structure and low emissivity structure.

Thus, according to embodiments of the present invention, a photovoltaic structure with a first predetermined color is paired with a low emissivity structure with a second predetermined color. The first predetermined color and the second predetermined color complement each other and provide an IGU incorporating the photovoltaic structure and the low emissivity structure that has a color that is more color neutral than both the photovoltaic structure and the low emissivity structure.

FIG. 5B demonstrates that embodiments of the present invention, which pair a photovoltaic structure with a complementary low emissivity structure, prevent the IGU from being characterized by a deep green color, which would result from integration of a photovoltaic structure with a conventional IGU that included a conventional low emissivity structure. Since the color of the photovoltaic structure and the low emissivity structure would generally be additive, integration of a photovoltaic structure with a low emissivity structure having a blue-green tint would result in an IGU with a color in the region of a*=−15; b*=15, which is a deep green unsuitable for most commercial and residential applications. In contrast, embodiments of the present invention, by using a photovoltaic structure and a low emissivity structure that are complementary, provide a color neutral IGU.

As can be seen in FIG. 4B, most low emissivity structures have positive b* values. Use of these conventional low emissivity structures, in combination with a photovoltaic structure having a color characteristic illustrated by oval 550, would only augment the b* value for the IGU, resulting in an undesirable green-yellow color. Because conventional low emissivity structures are designed in the absence of a photovoltaic structure, most conventional low emissivity structures do not have negative b* values and, thus, are unable to appropriately compensate for the b* value of photovoltaic structures.

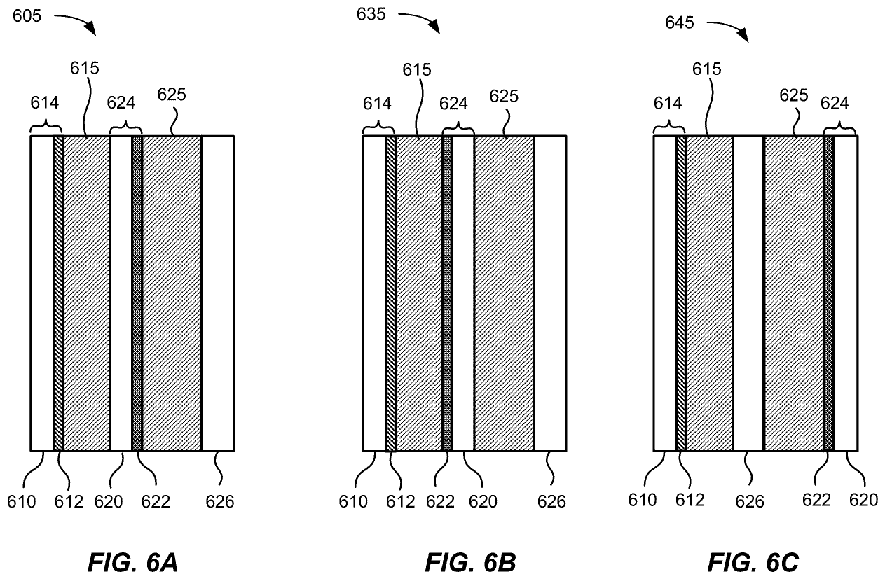

FIG. 6A is a simplified schematic diagram illustrating an insulated glass unit incorporating a photovoltaic coating, a low emissivity coating, and a glass lite according to an embodiment of the present invention. As illustrated in FIG. 6A, and in a manner similar to IGU 505 illustrated in FIG. 5A, a first lite 610 (i.e., a first piece of glass) is coated with a photovoltaic coating 612 (i.e., photovoltaic coating 612 is disposed on a surface of first lite 610) to form a photovoltaic structure 614. A second lite 620 (i.e., a second piece of glass) is coated with a low emissivity coating 622 (i.e., low emissivity coating 622 is disposed on a surface of second lite 620) to form a low emissivity structure 624. Photovoltaic structure 614 and low emissivity structure 624 are assembled with gap 615 separating photovoltaic structure 614 and low emissivity structure 624. In contrast with the embodiment illustrated in FIG. 5A, in which low emissivity coating 522 abutted gap 530, low emissivity coating 622 abuts second gap 625 separating low emissivity structure 624 and glass lite 626. IGU 605 is formed by assembling photovoltaic structure 614 and low emissivity structure 624 separated by gap 615 with glass lite 626 separated from low emissivity structure 624 by second gap 625. Gap 615 and second gap 625 can be filled with the same or different gases, including air, an inert gas such as vacuum, air, argon, krypton, xenon, or another gas such as nitrogen, combinations thereof, or the like. In the embodiment illustrated in FIG. 6A, photovoltaic coating 612 is disposed on a surface of first lite 610 facing toward second lite 620 and low emissivity coating 622 is disposed on a surface of second lite 620 facing away from first lite 610. In a manner similar to FIG. 5A, solar radiation is incident on the IGU illustrated in FIG. 6A, as well as those illustrated in FIGS. 6B-6C and 7A-7C, from the left side of the figure. Accordingly, the photovoltaic structures are positioned on the outside of the IGU.

FIG. 6B is a simplified schematic diagram illustrating an insulated glass unit incorporating a photovoltaic coating, a low emissivity coating, and a glass lite according to an alternative embodiment of the present invention. IGU 635 illustrated in FIG. 6B is similar to IGU 605 illustrated in FIG. 6A with the modification of the orientation of low emissivity structure 624. In this embodiment, low emissivity coating 622 abuts gap 615 in a manner similar to that illustrated in FIG. 5A. Accordingly, IGU 635 is formed by assembling photovoltaic structure 614 and low emissivity structure 624 separated by gap 615, with low emissivity coating 622 abutting gap 615, and with glass lite 626 separated from low emissivity structure 624 by second gap 625. In the embodiment illustrated in FIG. 6B, photovoltaic coating 612 is disposed on a surface of first lite 610 facing toward second lite 620 and low emissivity coating 622 is disposed on a surface of second lite 620 facing toward first lite 610 and photovoltaic coating 612. Additionally, in this embodiment, photovoltaic structure 614 is separated from low emissivity structure 624 by gap 615 and glass lite 626 is separated from low emissivity structure 624 by a second gap.

FIG. 6C is a simplified schematic diagram illustrating an insulated glass unit incorporating a photovoltaic coating, a low emissivity coating, and a glass lite according to another alternative embodiment of the present invention. In this implementation, the position of low emissivity structure 624 and glass lite 626 have been interchanged with respect to the positions illustrated in FIG. 6B. Accordingly, IGU 645 is formed by assembling photovoltaic structure 614 and glass lite 626 separated by gap 615, with low emissivity structure 624 separated from glass lite 626 by second gap 625 and low emissivity coating 622 abutting second gap 625. In the embodiment illustrated in FIG. 6C, photovoltaic coating 612 is disposed on a surface of first lite 610 facing toward glass lite 626, low emissivity coating 622 is disposed on a surface of second lite 620 facing toward first lite 610, and glass lite 626 is disposed between photovoltaic structure 614 and low emissivity structure 624. Additionally, photovoltaic structure 614 is separated from glass lite 626 by gap 615 and glass lite 626 is separated from low emissivity structure 624 by second gap 625.

In addition to dual pane and triple pane constructions discussed above, some embodiments of the present invention can utilize laminated constructions. As illustrated in FIGS. 7A-7C, the photovoltaic coating can be laminated to either another lite or to the low emissivity lite. As will be evident to one of skill in the art, these embodiments may be desirable for fabrication purposes and/or for safety reasons.

FIG. 7A is a simplified schematic diagram illustrating a laminated insulated glass unit incorporating a photovoltaic coating, a low emissivity coating, and a glass lite according to an embodiment of the present invention. In the embodiment illustrated in FIG. 7A, photovoltaic structure 714, which includes a first lite 710 and a photovoltaic coating 712 similar to first lite 610 and photovoltaic coating 612 that form photovoltaic structure 614, is laminated to glass lite 715 using lamination material 707. Examples of lamination materials include polyvinyl butyral (PVB), ethylene-vinyl acetate (EVA), and thermoplastic polyurethane (TPU). In this embodiment, lamination material 707 joins photovoltaic coating 712 and glass lite 715. Low emissivity structure 724, which includes a second lite 720 and a low emissivity coating 722 similar to second lite 620 and low emissivity coating 622 that form low emissivity structure 624, is separated from the laminated structure including photovoltaic structure 714 and glass lite 715 by gap 725. In this embodiment, photovoltaic coating 712 is disposed on a surface of first lite 710 and low emissivity coating 722 is disposed on a surface of second lite 720. Specifically, photovoltaic coating 712 is disposed on a surface of first lite 710 facing toward glass lite 715 and second lite 720 and low emissivity coating 722 is disposed on a surface of second lite 720 facing toward glass lite 715 and first lite 710. Thus, IGU 705 is formed by assembling the laminated structure including photovoltaic structure 714, lamination material 707, and glass lite 715 such that low emissivity structure 724 is separated from the laminated structure by gap 725. Although a glass lite 715 is illustrated in FIG. 7A, it will be appreciated that other suitable materials can be used to form the lite including materials with sufficient transparency and mechanical rigidity, including plexiglass, polycarbonate sheeting, or acrylic sheeting.

FIG. 7B is a simplified schematic diagram illustrating a laminated insulated glass unit incorporating a photovoltaic coating, a low emissivity coating, and a glass lite according to an alternative embodiment of the present invention. In this embodiment, photovoltaic structure 714, which includes a first lite 710 and a photovoltaic coating 712 similar to first lite 610 and photovoltaic coating 612 that form photovoltaic structure 614, is laminated to low emissivity structure 724, which includes a second lite 720 and a low emissivity coating 722 similar to second lite 620 and low emissivity coating 622 that form low emissivity structure 624, using lamination material 707. Thus, in this exemplary embodiment, lamination material 707 joins photovoltaic coating 712 and second lite 720. Glass lite 715 is separated from the laminated structure including photovoltaic structure 714, lamination material 707, and low emissivity structure 724 by gap 725. In the illustrated embodiment, photovoltaic structure 714 includes photovoltaic coating 712 disposed on a surface of first lite 710 facing toward glass lite 715 and low emissivity structure 724 includes low emissivity coating 722 disposed on a surface of second lite 720 facing toward glass lite 715. Thus, IGU 735 is formed by assembling the laminated structure including photovoltaic structure 714, lamination material 707, and low emissivity structure 724 such that glass lite 715 is separated from the laminated structure by gap 725. By placing the low emissivity structure 724 on the outboard side of the IGU, benefits available using conventional low emissivity windows are provided in conjunction with the power generation capability provided by photovoltaic structure 714. Although a glass lite 715 is illustrated in FIG. 7B, it will be appreciated that other suitable materials can be used to form the lite including materials with sufficient transparency and mechanical rigidity, including plexiglass, polycarbonate sheeting, or acrylic sheeting.

FIG. 7C is a simplified schematic diagram illustrating a laminated insulated glass unit incorporating a photovoltaic coating, a low emissivity coating, and a glass lite according to another alternative embodiment of the present invention. In this embodiment, photovoltaic structure 714, which includes a first lite 710 and a photovoltaic coating 712 similar to first lite 610 and photovoltaic coating 612 that form photovoltaic structure 614, is laminated to low emissivity structure 724, which includes a second lite 720 and a low emissivity coating 722 similar to second lite 620 and low emissivity coating 622 that form low emissivity structure 624, using lamination material 707 with the photovoltaic coating 712 and the low emissivity coating 722 abutting lamination material 707. Similar to IGU 735, glass lite 715 is separated from the laminated structure including photovoltaic structure 714, lamination material 707, and low emissivity structure 724 by gap 725. Thus, IGU 745 is formed by assembling the laminated structure including photovoltaic structure 714, lamination material 707, and low emissivity structure 724 such that glass lite 715 is separated from the laminated structure by gap 725.

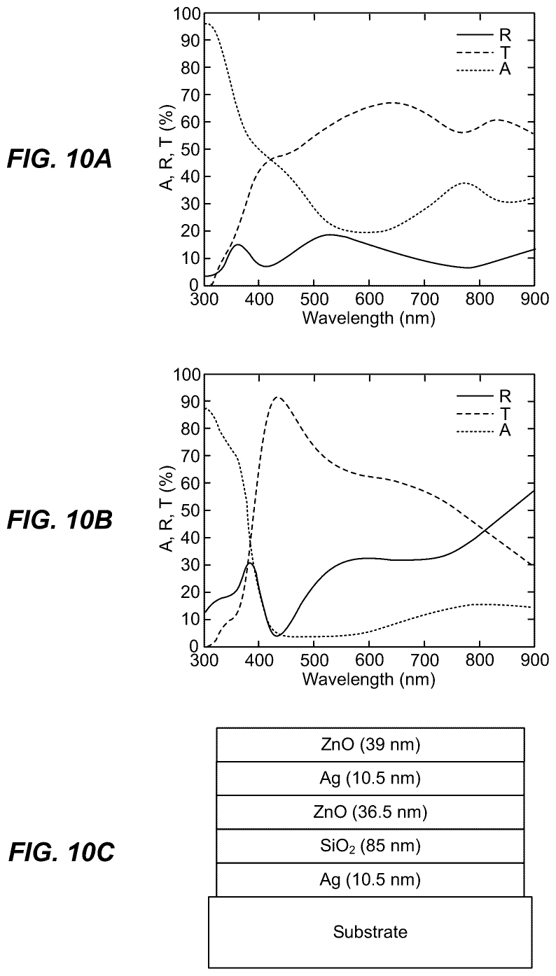

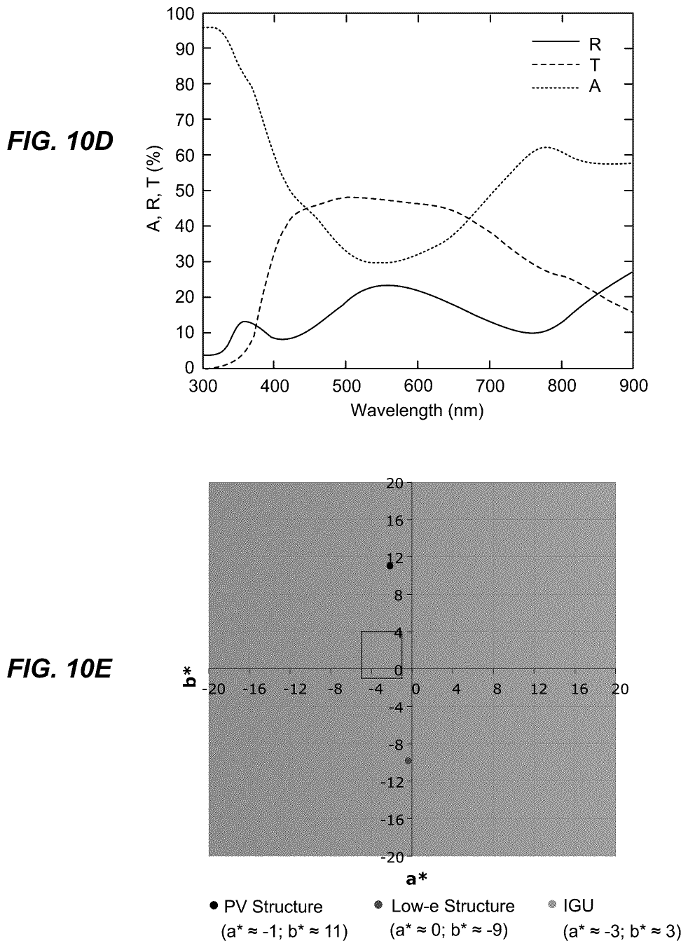

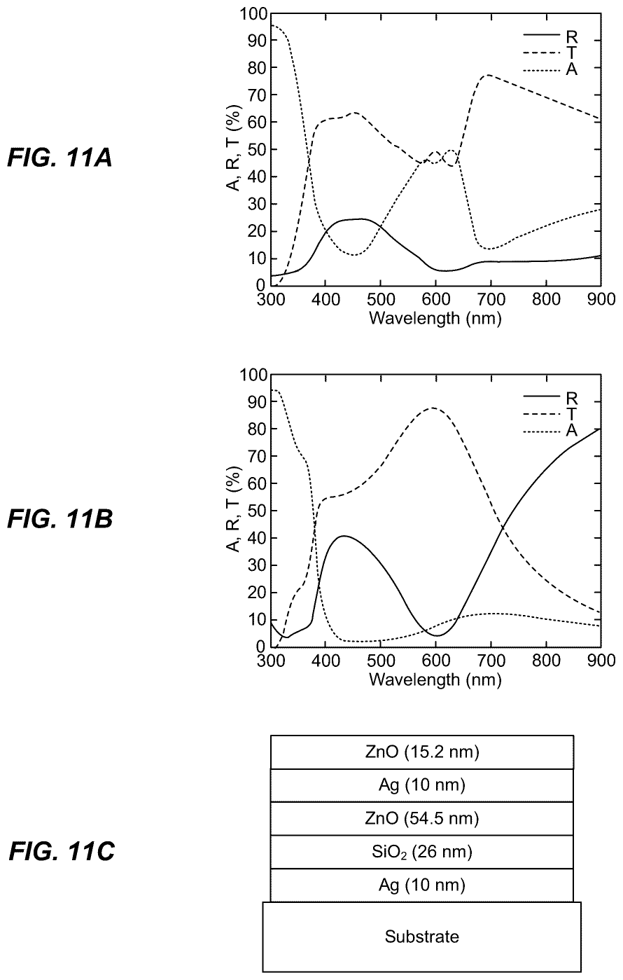

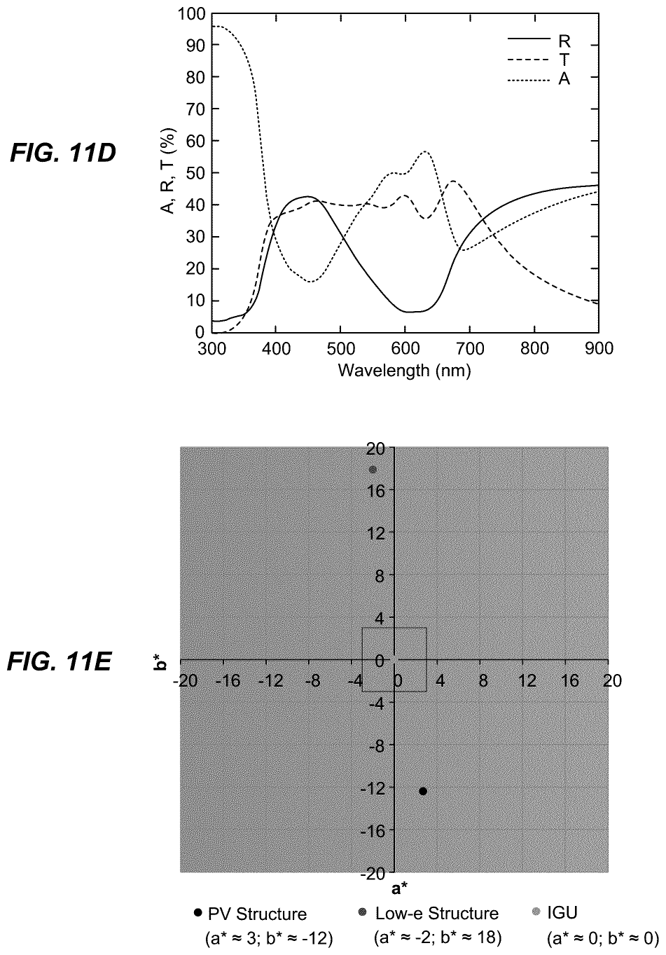

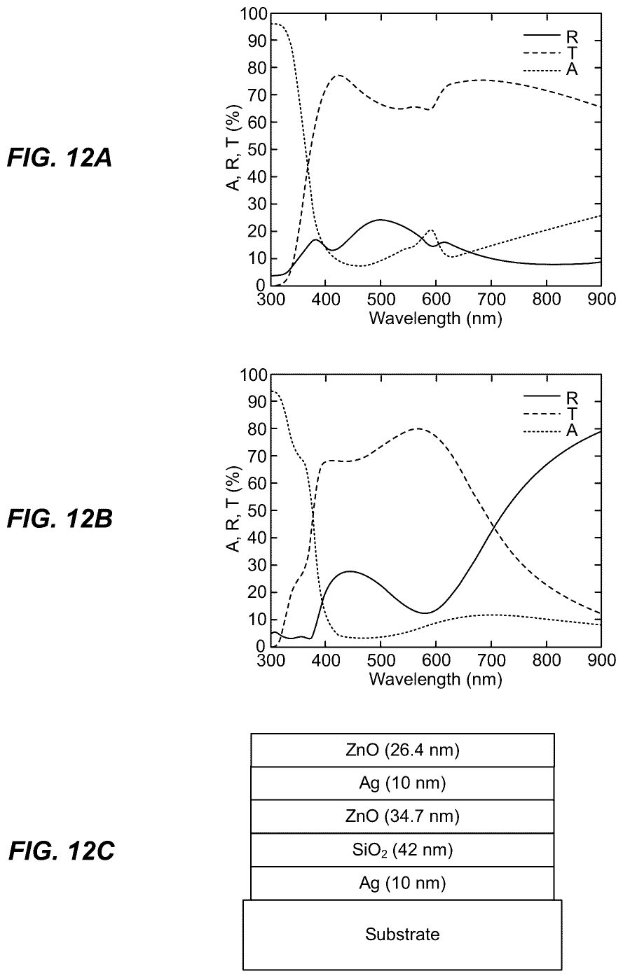

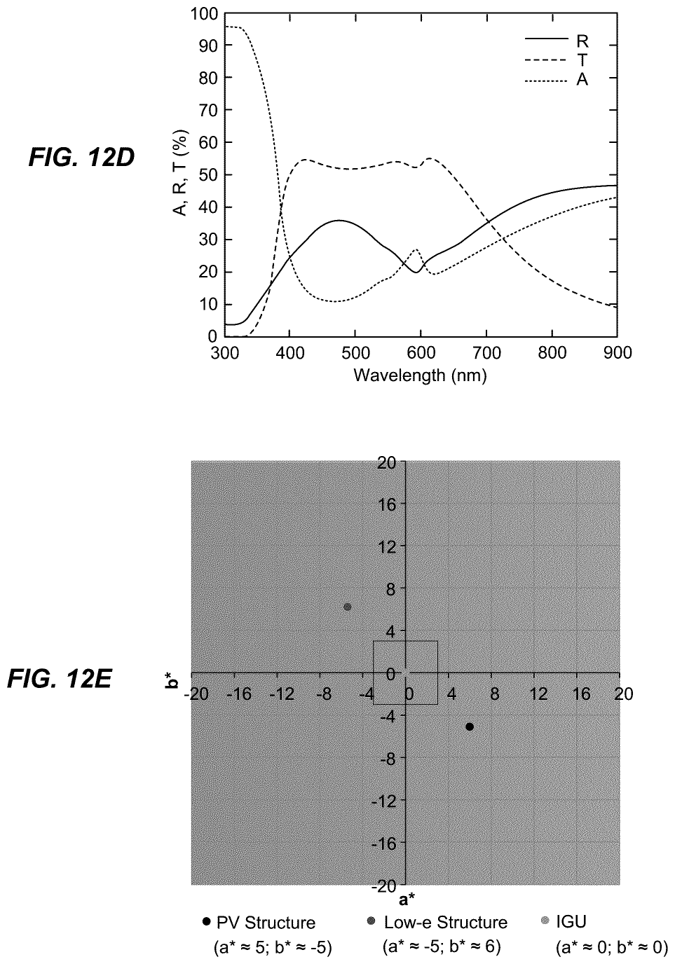

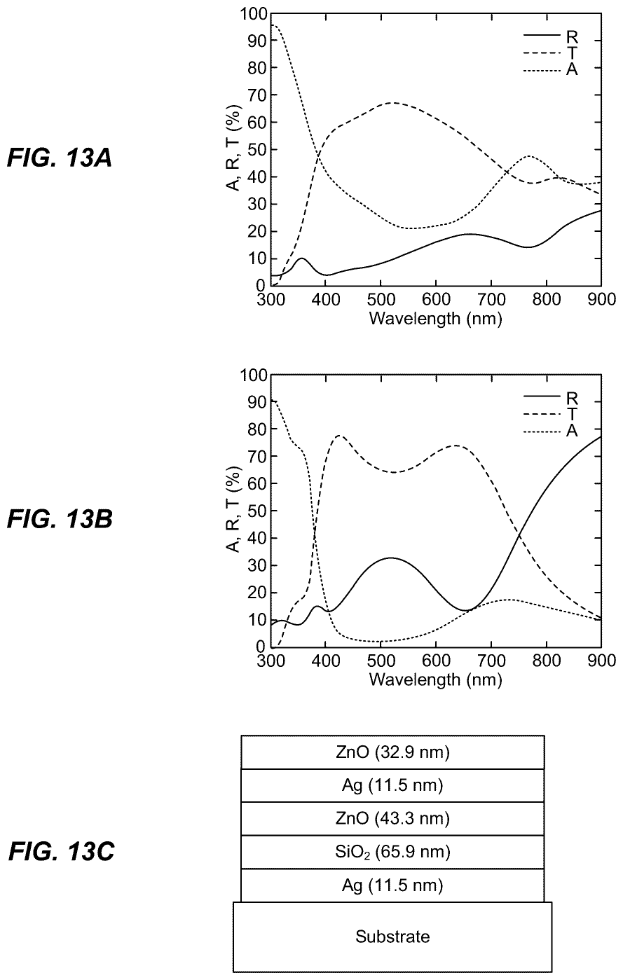

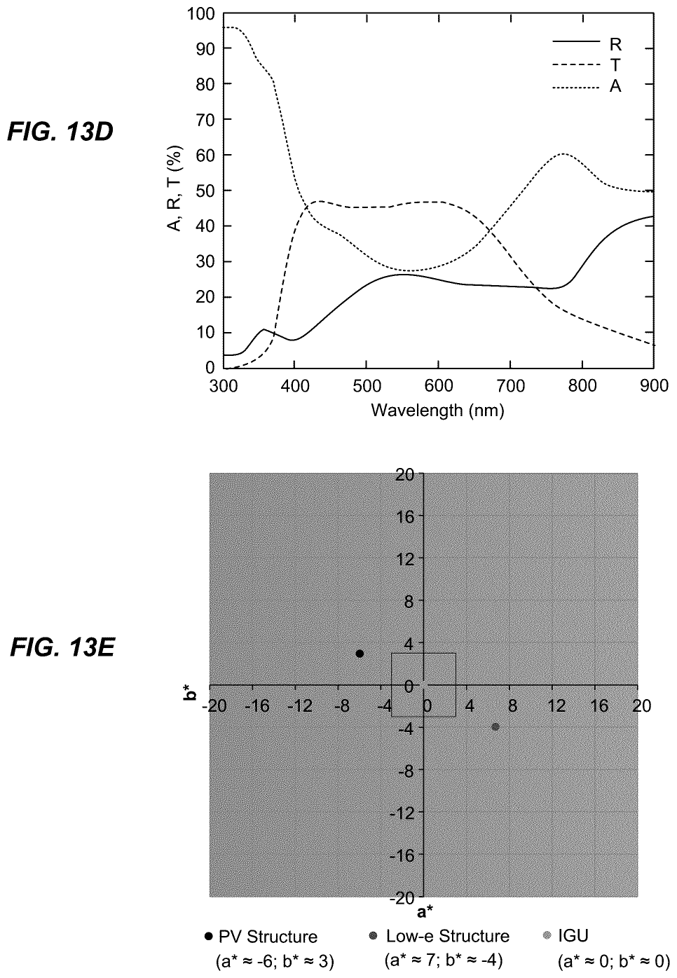

In the first embodiment discussed in relation to FIGS. 9A-9E and 10A-10E, the second embodiment discussed in relation to FIGS. 11A-11E, the third embodiment discussed in relation to FIGS. 12A-12E, and the fourth embodiment discussed in relation to FIGS. 13A-13E, the structure illustrated in FIG. 5A is utilized, with two glass lites having coatings on the inside surfaces separated by a gap, however other IGU constructions can be utilized within the scope of the present invention, including any of the constructions illustrated in FIGS. 6A-6C and 7A-C. The details of the construction including gap thickness, lamination, additional glass panels, and the like can be varied and/or altered within the scope of the present invention and these variations and/or alterations will not modify the principles of the various embodiments of the present invention as described herein.

The following figures illustrate four general classes of photovoltaic transmission and complementary low emissivity transmission, the combination of which results in a color neutral IGU. These four classes are: a) photovoltaic structure primarily transmits red light, low emissivity structure primarily transmits blue light; b) photovoltaic structure primarily transmits blue light, low emissivity structure primarily transmits red light; c) photovoltaic structure primarily transmits red and blue light, low emissivity structure primarily transmits green light; d) photovoltaic structure primarily transmits green light, low emissivity structure primarily transmits red and blue light.

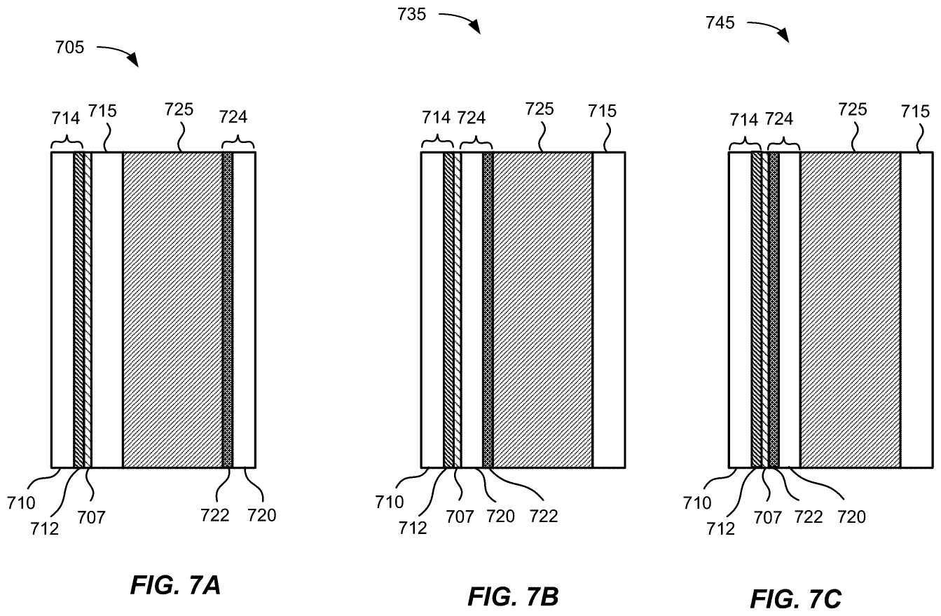

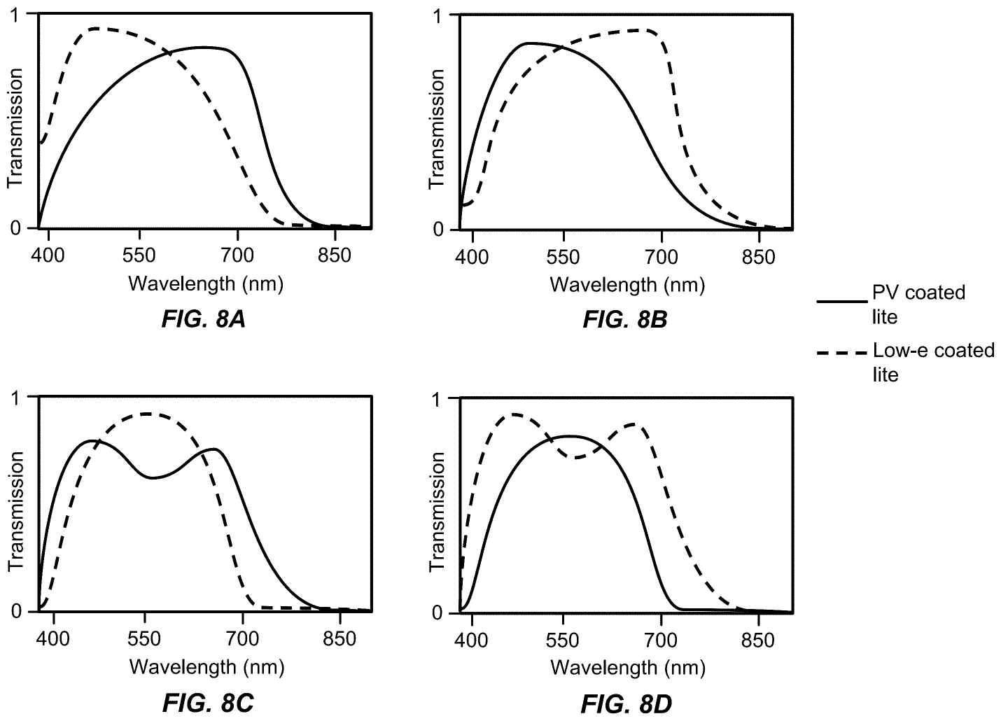

FIGS. 8A-8D illustrate these four general classes. FIG. 8A illustrates a plot of transmission vs. wavelength for a photovoltaic structure that transmits red light and a low emissivity structure that transmits blue light. FIG. 8B illustrates a plot of transmission vs. wavelength for a photovoltaic structure that transmits blue light and a low emissivity structure that transmits red light. FIG. 8C illustrates a plot of transmission vs. wavelength for a photovoltaic structure that transmits red and blue light and a low emissivity structure that transmits green light. FIG. 8D illustrates a plot of transmission vs. wavelength for a photovoltaic structure that transmits green light and a low emissivity structure that transmits red and blue light.

According to a first embodiment of the present invention, a photovoltaic structure that preferentially transmits red light is combined with a low emissivity structure that preferentially transmits blue light to provide a color neutral IGU.

FIG. 9A is a plot illustrating simulated optical properties of a photovoltaic structure according to a first embodiment of the present invention. As illustrated in FIG. 9A, the photovoltaic structure has greater absorption in the blue portion of the spectrum than in the green or red portions of the spectrum. As a result, the photovoltaic structure transmits red wavelengths preferentially in comparison with blue wavelengths. This higher transmission at red wavelengths results in a b* value for the photovoltaic structure that is positive. For the particular photovoltaic structure having the optical properties shown in FIG. 9A, b*=12.

FIG. 9B is a plot illustrating simulated optical properties of a low emissivity structure according to the first embodiment of the present invention. In contrast with the photovoltaic structure illustrated in relation to FIG. 9A, the low emissivity structure has greater transmission at blue wavelengths than at green and red wavelengths. As will be evident in FIG. 9E, the high transmission at blue wavelengths results in a b* value for the low emissivity structure that is significantly more negative than the b* values typically associated with low emissivity structures. For the particular low emissivity structure having the optical properties shown in FIG. 9B, b*≈−16, resulting in a purple color for the low emissivity structure.

FIG. 9C is a simplified schematic diagram illustrating layers in the low emissivity structure having the optical properties shown in FIG. 9B. In FIG. 9C, a low emissivity stack is illustrated as a series of layers deposited on a substrate (e.g., a glass substrate) as a series of coatings. The low emissivity stack includes a silver layer with a thickness of 10.5 nm, a zinc oxide (ZnO) layer with a thickness of 62 nm, a second silver layer with a thickness of 7.4 nm, and a second ZnO layer with a thickness of 51.8 nm.

As will be evident to one of skill in the art, the particular low emissivity stack illustrated in FIG. 9C was designed to achieve the optical properties illustrated in FIG. 9B, but the details of these stacks, such as material choices, layer thicknesses, and number of layers can be modified as appropriate to the particular application and many combinations can be utilized to achieve the optical properties illustrated in FIG. 9B. As will be appreciated, the particular low emissivity stack illustrated in FIG. 9C may not be stable as a discrete structure and is provided merely to demonstrate that low emissivity stacks with predetermined optical properties may be utilized according to embodiments of the present invention.

FIG. 9D is a plot illustrating simulated optical properties of an IGU incorporating the photovoltaic structure having the optical properties shown in FIG. 9A and the low emissivity structure having the optical properties shown in FIG. 9B. As illustrated in FIG. 9D, the IGU is characterized by generally uniform transmission across the visible spectrum, providing an average visible transmission (AVT) of ˜45% at visible wavelengths. In comparison with the photovoltaic structure having the optical properties shown in FIG. 9A, which is characterized by a yellow color, and the low emissivity structure having the optical properties shown in FIG. 9B, which is characterized by a purple color, the IGU having the optical properties shown in FIG. 9D is color neutral and gray.

As illustrated in FIGS. 9A, 9B, and 9D, in order to achieve an AVT for the IGU of greater than 40%, the AVT of both the photovoltaic structure and the low emissivity structure are in the range of ˜60-70%. In this embodiment, the AVT of the photovoltaic structure is ˜60% and the AVT of the low emissivity structure is ˜70%, resulting in an IGU with an AVT of ˜45%. Thus, embodiments of the present invention contrast with conventional TPV devices that have an AVT less than 50%. For these conventional, low AVT TPV devices, the combination with a low emissivity structure having an AVT of ˜70% would result in an IGU with an AVT of less than 40%. In fact, an IGU with such a low AVT would generally be unsuitable for residential and commercial applications. Particularly, TPV devices with an AVT of 20% or less would clearly be unsuitable for combination with a low emissivity structure since the combination would result in an IGU having an AVT percentage in the teens or less, which may prevent the IGU from being considered to be a transparent IGU. Thus, embodiments of the present invention, which can utilize photovoltaic structures having AVT values greater than 50% or higher, are ideally suited for color neutralization in an IGU using a low emissivity structure.

FIG. 9E is a CIELAB color space illustrating the color of the photovoltaic structure having the optical properties shown in FIG. 9A, the low emissivity structure having the optical properties shown in FIG. 9B, and the IGU having the optical properties shown in FIG. 9D. Referring back to FIGS. 9A and 9B, the transmission profiles for the photovoltaic structure and the low emissivity structure are complementary, with the photovoltaic structure preferentially transmitting red wavelengths and the low emissivity structure preferentially transmitting blue wavelengths. As a result, despite the colors of the photovoltaic structure and the low emissivity structure not being suitable for most applications, since the photovoltaic structure is yellow (a*≈1; b*≈12) and the low emissivity structure is purple (a*≈3; b*≈−16), the color of the IGU is gray (a*≈0; b*≈0). As will be discussed in relation to FIGS. 9A-9E, the pairing of the complementary photovoltaic structure and low emissivity structure does not require a gray IGU and other colors can be achieved for the IGU depending on the specific structures utilized and the colors achieved for the photovoltaic structure and the low emissivity structure.

Referring to FIG. 9E, the color of the low emissivity structure is a*≈3; b*≈˜16, which is a purple color. Absent the presence of the photovoltaic structure in the IGU, the use of this low emissivity structure would result in an IGU with an undesirable color for most applications, which would not benefit from use of a purple window. However, despite how undesirable this low emissivity structure would be when used in a conventional IGU, a low emissivity structure with this highly negative b* value, combined with a photovoltaic structure having a high positive b* value, results in a color neutral IGU. Accordingly, using components that, individually, would be unsuitable for the vast majority of applications, an IGU can be provided that has a color associated with a conventional low emissivity window. In fact, the extreme characters of the low emissivity structure with a low b* value and the photovoltaic structure with a high b* value, because they are complementary, result in a color neutral IGU that can be tailored to have a predetermined, desirable color. Therefore, using a low emissivity structure that is intentionally designed to have an undesirable color outside the conventional color box (i.e., −15<a*<0; −4<b*<8), an IGU pairing the low emissivity structure with a photovoltaic structure can be implemented as a color neutral IGU.

As described more fully below, in the IGUs illustrated in FIGS. 9E, 11E, 12E and 13E, the color of the photovoltaic structure is completely neutralized using a low emissivity structure exactly complementary to the photovoltaic structure, resulting in a completely neutralized IGU (i.e., an IGU with a color of a*=0; b*=0). The ability to precisely control the layer thicknesses and compositions of both the photovoltaic structure and the low emissivity structure enable this high level of color control.

However, for most residential and commercials applications, it is preferable to have an IGU that, rather than being gray, has a desirable green or blue color as discussed in relation to FIG. 4B. Since most photovoltaic structures, due to the nature of absorption in organic semiconductors, have large, positive b* values, for example, b*>10, the b* value is reduced by the use of a complementary low emissivity structure with a negative b* value to achieve an IGU with a more neutral color.

Thus, as described in relation to FIGS. 9A-9E, a low emissivity structure is utilized, not to completely neutralize the color of the photovoltaic structure, but to shift the color of the photovoltaic structure into the color box characteristic of most conventional IGUs. In this example, a low emissivity structure with a highly negative b* is utilized to compensate for the positive b* that characterizes the photovoltaic structure due to absorption in the UV region of the color spectrum tailing into the visible, thereby resulting in absorption of blue light.

FIG. 10A is a plot illustrating simulated optical properties of a photovoltaic structure according to a first alternative embodiment of the present invention. In a manner similar to the photovoltaic structure illustrated in FIG. 10A, the photovoltaic structure has greater absorption in the blue portion of the spectrum than in the green or red portions of the spectrum. As a result, the photovoltaic structure transmits red wavelengths preferentially in comparison with blue wavelengths. This higher transmission at red wavelengths results in a b* value for the photovoltaic structure that is positive. For the particular photovoltaic structure having the optical properties shown in FIG. 10A, b*=11.

FIG. 10B is a plot illustrating simulated optical properties of a low emissivity structure according to the first alternative embodiment of the present invention. In a manner similar to the photovoltaic structure illustrated in FIG. 10B, the low emissivity structure has greater transmission at blue wavelengths than at green and red wavelengths. As will be evident in FIG. 10E, the high transmission at blue wavelengths results in a b* value for the low emissivity structure that is significantly more negative than the b* values typically associated with low emissivity structures. For the particular low emissivity structure having the optical properties shown in FIG. 10B, b*≈−9, resulting in a purple color for the low emissivity structure.

FIG. 10C is a simplified schematic diagram illustrating layers in the low emissivity structure having the optical properties shown in FIG. 10B. In FIG. 10C, a low emissivity stack is illustrated as a series of layers deposited on a substrate (e.g., a glass substrate) as a series of coatings. The low emissivity stack includes a silver layer with a thickness of 10.5 nm, a silicon dioxide (SiO₂) layer with a thickness of 85 nm, a zinc oxide (ZnO) layer with a thickness of 36.5 nm, a second silver layer with a thickness of 10.5 nm, and a second ZnO layer with a thickness of 39 nm.

As will be evident to one of skill in the art, the particular low emissivity stack illustrated in FIG. 10C was designed to achieve the optical properties illustrated in FIG. 10B, but the details of these stacks, such as material choices, layer thicknesses, and number of layers can be modified as appropriate to the particular application and many combinations can be utilized to achieve the optical properties illustrated in FIG. 10B.

FIG. 10D is a plot illustrating simulated optical properties of an IGU incorporating the photovoltaic structure having the optical properties shown in FIG. 10A and the low emissivity structure having the optical properties shown in FIG. 10B. As illustrated in FIG. 10D, the IGU is characterized by generally uniform transmission across the visible spectrum, providing an average visible transmission (AVT) of ˜45% at visible wavelengths. In comparison with the IGU having the optical properties shown in FIG. 10D, which is gray (i.e., a*=0; b*=0), the IGU having the optical properties shown in FIG. 10D is blue-green (i.e., a*=−3; b*=3), which is a color associated with conventional IGUs including a low emissivity coating.

FIG. 10E is a CIELAB color space illustrating the color of the photovoltaic structure having the optical properties shown in FIG. 10A, the low emissivity structure having the optical properties shown in FIG. 10B, and the IGU having the optical properties shown in FIG. 10D. Referring back to FIGS. 10A and 10B, the transmission profiles for the photovoltaic structure and the low emissivity structure are complementary, with the photovoltaic structure preferentially transmitting red wavelengths and the low emissivity structure preferentially transmitting blue wavelengths. As a result, despite the colors of the photovoltaic structure and the low emissivity structure not being suitable for most applications, since the photovoltaic structure is yellow (a*≈−1; b*≈11) and the low emissivity structure is purple (a*≈0; b*≈−9), the simulated color of the IGU is blue-green (a*≈−3; b*≈3). Thus, the pairing of the complementary photovoltaic structure and low emissivity structure results in a color that, rather than gray as illustrated in FIG. 10E, provides another predetermined color.

Accordingly, complementary photovoltaic and low emissivity structures are utilized, not to completely neutralize the color of the photovoltaic structure, but to shift the color of the photovoltaic structure into the color box characteristic of most conventional IGUs. The ability to precisely control the layer thicknesses and compositions of both the photovoltaic structure and the low emissivity structure enable this high level of color control.

It should be noted with respect to FIG. 10E that the color of the IGU (a*≈−3; b*≈3) is characterized by an a* value for which the absolute value is greater than the absolute value of both the a* value for the photovoltaic structure (a*≈−1) and the a* value for the low emissivity structure (a*≈0). Although this would appear to indicate that the color of the IGU has not been “neutralized” by the combination of the photovoltaic structure and the low emissivity structure in the IGU, inspection of FIG. 10E will indicate that the IGU is color neutral because, with respect to both the photovoltaic structure and the low emissivity structure, the color of the IGU is closer to the origin of the color space than either the color of the photovoltaic structure or the color of the low emissivity structure. Accordingly, the IGU illustrated in relation to FIG. 10E is color neutral with respect to the components because the absolute value of the b* value for the IGU is less than both the b* value for the photovoltaic structure and the absolute value of the b* value for the low emissivity structure.

According to a second embodiment of the present invention, a photovoltaic structure that preferentially transmits blue light is combined with a low emissivity coating that preferentially transmits red light to provide a color neutral IGU. In the embodiment that follows, the photovoltaic structure has higher transmission at blue wavelengths (i.e., −450 nm) than at green wavelengths (i.e., ˜550 nm) and red wavelengths (i.e., ˜625 nm). These spectral characteristics could result from a photovoltaic coating that absorbs in the IR, with the absorption profile tailing into red wavelengths. Accordingly, a complementary low emissivity structure with higher transmission at red wavelengths is used in this embodiment to provide an IGU that is color neutral with respect to the colors of the photovoltaic structure and the low emissivity structure.

FIG. 11A is a plot illustrating simulated optical properties of a photovoltaic structure according to a second embodiment of the present invention. As illustrated in FIG. 11A, the photovoltaic structure has greater absorption in the red portion of the spectrum than in the blue portion of the spectrum. As a result, the photovoltaic structure transmits blue wavelengths preferentially in comparison with red wavelengths. This higher transmission at blue wavelengths results in a b* value for the photovoltaic structure that is negative. For the particular photovoltaic structure having the optical properties shown in FIG. 11A, b*=−12.

FIG. 11B is a plot illustrating simulated optical properties of a low emissivity structure according to the second embodiment of the present invention. In contrast with the photovoltaic structure illustrated in relation to FIG. 11A, the low emissivity structure has greater transmission at red wavelengths than at blue wavelengths. As will be evident in FIG. 11E, the high transmission at red wavelengths results in a b* value for the low emissivity structure that is significantly more positive than the b* values typically associated with low emissivity structures. For the particular low emissivity structure having the optical properties shown in FIG. 11B, b*≈18, resulting in a yellow color for the low emissivity structure.

FIG. 11C is a simplified schematic diagram illustrating layers in the low emissivity structure having the optical properties shown in FIG. 11B. In FIG. 11C, a low emissivity stack is illustrated as a series of layers deposited on a substrate (e.g., a glass substrate) as a series of coatings. The low emissivity stack includes a silver layer with a thickness of 10 nm, a silicon oxide (SiO₂) layer with a thickness of 26 nm, a zinc oxide (ZnO) layer with a thickness of 54.5 nm, a second silver layer with a thickness of 10 nm, and a second ZnO layer with a thickness of 15.2 nm.

As will be evident to one of skill in the art, the particular low emissivity stack illustrated in FIG. 11C was designed to achieve the optical properties illustrated in FIG. 11B, but the details of these stacks, such as material choices, layer thicknesses, and number of layers can be modified as appropriate to the particular application and many combinations can be utilized to achieve the optical properties illustrated in FIG. 11B.

FIG. 11D is a plot illustrating simulated optical properties of an IGU incorporating the photovoltaic structure having the optical properties shown in FIG. 11A and the low emissivity structure having the optical properties shown in FIG. 11B. As illustrated in FIG. 11D, the IGU is characterized by generally uniform transmission across the visible spectrum, providing an average visible transmission (AVT) of ˜40% at visible wavelengths. In comparison with the photovoltaic structure having the optical properties shown in FIG. 11A, which is characterized by a purple color, and the low emissivity structure having the optical properties shown in FIG. 11B, which is characterized by a yellow color, the IGU having the optical properties shown in FIG. 11D is color neutral and gray.

FIG. 11E is a CIELAB color space illustrating the color of the photovoltaic structure having the optical properties shown in FIG. 11A, the low emissivity structure having the optical properties shown in FIG. 11B, and the IGU having the optical properties shown in FIG. 11D. Referring back to FIGS. 11A and 11B, the transmission profiles for the photovoltaic structure and the low emissivity structure are complementary, with the photovoltaic structure preferentially transmitting blue wavelengths and the low emissivity structure preferentially transmitting red wavelengths. As a result, despite the colors of the photovoltaic structure and the low emissivity structure not being suitable for most applications, since the photovoltaic structure is purple (a*≈3; b*≈−12) and the low emissivity structure is yellow (a*≈−2; b*≈18), the color of the IGU is gray (a*≈0; b*≈0). As discussed herein, the pairing of the complementary photovoltaic structure and low emissivity structure does not require a gray IGU and other colors can be achieved for the IGU depending on the specific structures utilized and the colors achieved for the photovoltaic structure and the low emissivity structure.

Referring to FIG. 11E, the color of the low emissivity structure is a*≈−3; b*≈18, which is a yellow color. Absent the presence of the photovoltaic structure in the IGU, the use of this low emissivity structure would result in an IGU with an undesirable color for most applications, which would not benefit from use of a yellow window. However, despite how undesirable this low emissivity structure would be when used in a conventional IGU, a low emissivity structure with this extremely high b* value, combined with a photovoltaic structure having a low b* value, results in a color neutral IGU. Accordingly, using components that, individually, would be unsuitable for the vast majority of applications, an IGU can be provided that has a color associated with a conventional low emissivity window. In fact, the extreme characters of the low emissivity structure with a high b* value and the photovoltaic structure with a low b* value, because they are complementary, result in a color neutral IGU that can be tailored to have a predetermined, desirable color. Therefore, using a low emissivity structure that is intentionally designed to have an undesirable color outside the conventional color box, an IGU pairing the low emissivity structure with a photovoltaic structure can be implemented as a color neutral IGU.

As discussed above, the pairing of the complementary photovoltaic structure and low emissivity structure does not require a gray IGU and other colors can be achieved for the IGU depending on the specific structures utilized and the colors achieved for the photovoltaic structure and the low emissivity structure.

According to a third embodiment of the present invention, a photovoltaic structure that preferentially transmits blue and red light is combined with a low emissivity coating that preferentially transmits green light to provide a color neutral IGU. In this embodiment, the photovoltaic structure is characterized by some absorption centered in the visible wavelength range, resulting in preferential transmission of red and blue wavelengths. This behavior could be associated with introduction of a visible absorber in the photovoltaic coating or an IR absorber that also includes an absorption feature in the visible portion of the optical spectrum. Accordingly, a complementary low emissivity structure with higher transmission at green wavelengths is used in this embodiment to provide an IGU that is color neutral with respect to the colors of the photovoltaic structure and the low emissivity structure.

FIG. 12A is a plot illustrating simulated optical properties of a photovoltaic structure according to a third embodiment of the present invention. As illustrated in FIG. 12A, the photovoltaic structure has greater absorption in the green portion of the spectrum than in the blue or red portions of the spectrum. As a result, the photovoltaic structure transmits blue and red wavelengths preferentially in comparison with green wavelengths. This higher transmission at blue and red wavelengths results in a b* value for the photovoltaic structure that is negative. For the particular photovoltaic structure having the optical properties shown in FIG. 12A, b*=−5.

FIG. 12B is a plot illustrating simulated optical properties of a low emissivity structure according to the third embodiment of the present invention. In contrast with the photovoltaic structure illustrated in relation to FIG. 12A, the low emissivity structure has greater transmission at green wavelengths than at blue and red wavelengths. As will be evident in FIG. 12E, the high transmission at green wavelengths results in a b* value for the low emissivity structure that is slightly higher than the b* values typically associated with low emissivity structures. For the particular low emissivity structure having the optical properties shown in FIG. 12B, b*≈6, resulting in a blue-green color for the low emissivity structure.

FIG. 12C is a simplified schematic diagram illustrating layers in the low emissivity structure having the optical properties shown in FIG. 12B. In FIG. 12C, a low emissivity stack is illustrated as a series of layers deposited on a substrate (e.g., a glass substrate) as a series of coatings. The low emissivity stack includes a silver layer with a thickness of 10 nm, a silicon oxide (SiO₂) layer with a thickness of 42 nm, a zinc oxide (ZnO) layer with a thickness of 34.7 nm, a second silver layer with a thickness of 10 nm, and a second ZnO layer with a thickness of 26.4 nm.

As will be evident to one of skill in the art, the particular low emissivity stack illustrated in FIG. 12C was designed to achieve the optical properties illustrated in FIG. 12B, but the details of these stacks, such as material choices, layer thicknesses, and number of layers can be modified as appropriate to the particular application and many combinations can be utilized to achieve the optical properties illustrated in FIG. 12B.

FIG. 12D is a plot illustrating simulated optical properties of an IGU incorporating the photovoltaic structure having the optical properties shown in FIG. 12A and the low emissivity structure having the optical properties shown in FIG. 12B. As illustrated in FIG. 12D, the IGU is characterized by generally uniform transmission across the visible spectrum, providing an average visible transmission (AVT) of ˜50% at visible wavelengths. In comparison with the photovoltaic structure having the optical properties shown in FIG. 12A, which is characterized by a purple color, and the low emissivity structure having the optical properties shown in FIG. 12B, which is characterized by a blue-green color, the IGU having the optical properties shown in FIG. 12D is color neutral and gray.

FIG. 12E is a CIELAB color space illustrating the color of the photovoltaic structure having the optical properties shown in FIG. 12A, the low emissivity structure having the optical properties shown in FIG. 12B, and the IGU having the optical properties shown in FIG. 12D. Referring back to FIGS. 12A and 12B, the transmission profiles for the photovoltaic structure and the low emissivity structure are complementary, with the photovoltaic structure preferentially transmitting blue and red wavelengths and the low emissivity structure preferentially transmitting green wavelengths. As a result, despite the colors of the photovoltaic structure and the low emissivity structure not being suitable for most applications, since the photovoltaic structure is purple (a*≈5; b*≈−5) and the low emissivity structure is blue-green (a*≈−5; b*≈6), the color of the IGU is gray (a*≈0; b*≈0). As discussed above, the pairing of the complementary photovoltaic structure and low emissivity structure does not require a gray IGU and other colors can be achieved for the IGU depending on the specific structures utilized and the colors achieved for the photovoltaic structure and the low emissivity structure.

According to a fourth embodiment of the present invention, a photovoltaic structure that preferentially transmits green light is combined with a low emissivity coating that preferentially transmits blue and red light to provide a color neutral IGU. In the embodiment that follows, the photovoltaic structure has higher transmission at green wavelengths (i.e., ˜550 nm) than at blue wavelengths (i.e., ˜450 nm) and red wavelengths (i.e., ˜650 nm). These spectral characteristics could result from a photovoltaic coating that absorbs in both the UV and IR, with the absorption profiles tailing into violet and red wavelengths, respectively. Accordingly, a complementary low emissivity structure with higher transmission at blue and red wavelengths, which can be achieved by combining two transmission profiles, is used in this embodiment to provide an IGU that is color neutral with respect to the colors of the photovoltaic structure and the low emissivity structure.

FIG. 13A is a plot illustrating simulated optical properties of a photovoltaic structure according to a fourth embodiment of the present invention. As illustrated in FIG. 13A, the photovoltaic structure has greater absorption in the blue and red portions of the spectrum than in the green portion of the spectrum. As a result, the photovoltaic structure transmits green wavelengths preferentially in comparison with blue and red wavelengths. This higher transmission at green wavelengths results in a b* value for the photovoltaic structure that is positive. For the particular photovoltaic structure having the optical properties shown in FIG. 12A, b*=3.

FIG. 13B is a plot illustrating simulated optical properties of a low emissivity structure according to the fourth embodiment of the present invention. In contrast with the photovoltaic structure illustrated in relation to FIG. 13A, the low emissivity structure has greater transmission at blue and red wavelengths than at green wavelengths. As will be evident in FIG. 13E, the high transmission at blue and red wavelengths results in a b* value for the low emissivity structure that is significantly more negative than the b* values typically associated with low emissivity structures. For the particular low emissivity structure having the optical properties shown in FIG. 13B, b*≈−5, resulting in a purple color for the low emissivity structure.

FIG. 13C is a simplified schematic diagram illustrating layers in the low emissivity structure having the optical properties shown in FIG. 13B. In FIG. 13C, a low emissivity stack is illustrated as a series of layers deposited on a substrate (e.g., a glass substrate) as a series of coatings. The low emissivity stack includes a silver layer with a thickness of 11.5 nm, a silicon oxide (SiO₂) layer with a thickness of 65.9 nm, a zinc oxide (ZnO) layer with a thickness of 43.3 nm, a second silver layer with a thickness of 11.5 nm, and a second ZnO layer with a thickness of 32.9 nm.

As will be evident to one of skill in the art, the particular low emissivity stack illustrated in FIG. 13C was designed to achieve the optical properties illustrated in FIG. 13B, but the details of these stacks, such as material choices, layer thicknesses, and number of layers can be modified as appropriate to the particular application and many combinations can be utilized to achieve the optical properties illustrated in FIG. 13B.

FIG. 13D is a plot illustrating simulated optical properties of an IGU incorporating the photovoltaic structure having the optical properties shown in FIG. 13A and the low emissivity structure having the optical properties shown in FIG. 13B. As illustrated in FIG. 13D, the IGU is characterized by generally uniform transmission across the visible spectrum, providing an average visible transmission (AVT) of ˜45% at visible wavelengths. In comparison with the photovoltaic structure having the optical properties shown in FIG. 13A, which is characterized by a blue-green color, and the low emissivity structure having the optical properties shown in FIG. 13B, which is characterized by a purple color, the IGU having the optical properties shown in FIG. 13D is color neutral and gray.

FIG. 13E is a CIELAB color space illustrating the color of the photovoltaic structure having the optical properties shown in FIG. 13A, the low emissivity structure having the optical properties shown in FIG. 13B, and the IGU having the optical properties shown in FIG. 13D. Referring to FIG. 13B, the transmission peaks at blue and red wavelengths result in a low emissivity structure with a strongly purple/pink color that would be very undesirable if utilized in a conventional IGU. However, as illustrated in FIGS. 13D and 13E, pairing of this undesirable low emissivity structure with a complementary photovoltaic structure provides an IGU with high AVT (i.e., ˜50) and a color of a*=0; b*=0. Accordingly, using a low emissivity structure similar to that shown in FIG. 13C, the color of the photovoltaic structure, which may be more green than desired (i.e., a lower a* value and/or a higher b* value than desired), can be neutralized to achieve a color neutral IGU.

In particular, it should be noted that if the photovoltaic structure having the optical properties shown in FIG. 13A, which has a green color associated with conventional low emissivity IGUs, was inserted into a conventional low emissivity IGU, the color of the IGU would be shifted to a deeper and undesirable green color. As an example, if a conventional low emissivity IGU had a color of a*=−6, b*=3.3, which is the center color of the glass products shown in FIG. 4B, the insertion of the photovoltaic structure in such an IGU would result in the color of the IGU shifting to a color of a*≈−12, b*≈6, which would be far too green for most applications. By utilizing the low emissivity structure having a strongly purple/pink color as shown in this embodiment (a*≈7; b*≈−4), the green color of the photovoltaic structure (a*≈−6; b*≈3) is neutralized to provide a color neutral IGU (a*≈0; b*≈0). In an alternative embodiment, the color of the low emissivity structure would be closer to the center of the color space but still characterized by a positive a* value and a negative b* value (e.g., 0<a*<7; −4<b*<0). Use of this low emissivity structure in an IGU including the photovoltaic structure having the optical properties shown in FIG. 13A would result in an IGU more color neutral than the color of the photovoltaic structure but with a desirable color (e.g., a*≈−3, b*≈3).

Thus, the inventors have determined that the integration of a photovoltaic structure characterized by a negative a* value and a positive b* value results in an IGU having a color that is a deeper green than the IGU without the photovoltaic structure, producing an IGU color that is undesirable. In order to prevent the color of the IGU from being shifted to an undesirable color, embodiments of the present invention, rather than combining a conventional low emissivity structure with a photovoltaic structure in an IGU, utilize a low emissivity structure that would generally have a* and b* values higher/lower than desirable, respectively. Accordingly, embodiments of the present invention utilize a photovoltaic structure and a low emissivity structure that are complementary in color in order to provide an IGU that is more color neutral than either the photovoltaic structure or the low emissivity structure. In particular, utilizing complementary colors, a low emissivity structure that would be undesirable in isolation can provide the high a* value and low b* value appropriate to shift the color of the photovoltaic structure toward the center of the color space.

The low emissivity stacks illustrated in FIGS. 9C, 10C, 11C, 12C, and 13C all utilize a relatively simple version of the structure illustrated in FIG. 4A and use a simple set of example materials for the purpose of simulation and demonstration of the applicability of this technique. In practice, additional layers would likely be necessary for manufacturability and stability. More complicated structures, utilizing additional silver layers or additional dielectric layers would afford even greater control over the transmission spectrum of a low emissivity coated glass lite. The dielectric materials used in these simulations were simply proxies for the large set of dielectrics used currently in the low emissivity glass industry which includes, but is not limited to, silicon oxides (SiOₓ), silicon nitrides (SiNₓ), silicon oxynitrides (SiOₓN_{y}), tin oxides (SnOₓ), zinc oxides (ZnOₓ), zinc tin oxides (ZnSnOₓ), zirconium oxides (ZrOₓ), titanium oxides (TiOₓ), zinc titanium oxides (ZnTiOₓ), zinc aluminum oxides (ZnAlOₓ), and nickel chromium oxides (NiCrOₓ). The stoichiometry of the dielectrics can also be varied and not limited to the formulas shown. Likewise, in addition to silver, metals including, but not limited to, chromium (Cr), nickel chromium (NiCr), and titanium (Ti) are often used as capping layers in the low emissivity stacks. Substitution of these, or other materials into low emissivity structures of the type shown in FIG. 4A do not fundamentally change the aspects of embodiments of the present invention. The tunability of the color is a general property of these types of optical structures.

All references throughout this disclosure, for example, patent documents including issued or granted patents or equivalents; patent application publications; and non-patent literature documents or other source material; are hereby incorporated by reference herein in their entireties, as though individually incorporated by reference.

All patents and publications mentioned in this disclosure are indicative of the levels of skill of those skilled in the art to which the invention pertains. References cited herein are incorporated by reference herein in their entirety to indicate the state of the art, in some cases as of their filing date, and it is intended that this information can be employed herein, if needed, to exclude (for example, to disclaim) specific embodiments that are in the prior art. For example, when a compound is claimed, it should be understood that compounds known in the prior art, including certain compounds disclosed in the references disclosed herein (particularly in referenced patent documents), are not intended to be included in the claim.

When a group of substituents is disclosed herein, it is understood that all individual members of those groups and all subgroups and classes that can be formed using the substituents are disclosed separately. When a Markush group or other grouping is used herein, all individual members of the group and all combinations and sub-combinations possible of the group are intended to be individually included in the disclosure. As used herein, “and/or” means that one, all, or any combination of items in a list separated by “and/or” are included in the list; for example “1, 2 and/or 3” is equivalent to “‘1’ or ‘2’ or ‘3’ or ‘1 and 2’ or ‘1 and 3’ or ‘2 and 3’ or ‘1, 2 and 3’”.

Every formulation or combination of components described or exemplified can be used to practice the invention, unless otherwise stated. Specific names of materials are intended to be exemplary, as it is known that one of skill in the art can name the same material differently. It will be appreciated that methods, device elements, starting materials, and synthetic methods other than those specifically exemplified can be employed in the practice of the invention without resort to undue experimentation. All art-known functional equivalents, of any such methods, device elements, starting materials, and synthetic methods are intended to be included in this invention. Whenever a range is given in the specification, for example, a temperature range, a time range, or a composition range, all intermediate ranges and subranges, as well as all individual values included in the ranges given are intended to be included in the disclosure.

As used herein, “comprising” is synonymous with “including,” “containing,” “having,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of the recited components or elements. The invention illustratively described herein suitably may be practiced in the absence of any element or elements, limitation or limitations which is not specifically disclosed herein.

As used herein, the terms “a,” “an,” “the,” and similar referents in the context of describing the disclosed embodiments (especially in the context of the following claims) are to be construed to cover both the singular and the plural, unless otherwise indicated herein or clearly contradicted by context. The term “connected” is to be construed as partly or wholly contained within, attached to, or joined together, even if there is something intervening. Recitation of ranges of values herein is merely intended to serve as a shorthand method of referring individually to each separate value falling within the range, unless otherwise indicated herein and each separate value is incorporated into the specification as if it were individually recited herein. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is intended to be understood within the context as used in general to present that an item, term, and the like, may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered within the scope of this invention as defined by the appended claims.

1. An insulated glass unit (IGU) characterized by a transmitted IGU color (a*_{IGU}; b*_{IGU}), the IGU comprising:
a photovoltaic structure disposed on a surface of a first lite, wherein the photovoltaic structure covers the whole surface of the first lite and is characterized by a first transmitted color (a*₁; b*₁);
a low emissivity structure disposed on a surface of a second lite, wherein the low emissivity structure is configured to transmit light characterized by a second transmitted color (a*₂; b*₂) and reflect infrared light passed through the first lite and the photovoltaic structure, wherein the first transmitted color and the second transmitted color are complementary; and wherein the low emissivity structure comprises:
a first transparent dielectric layer disposed on the surface of the second lite;
one or more metal layers disposed on the first transparent dielectric layer; and
a second transparent dielectric layer disposed on the one or more metal layers; and
a gap filled with one or more gases, wherein the first lite and the second lite are separated by the gap.

2. The insulated glass unit of claim 1 wherein:

|a*_{IGU}|<|a*₁|; or

|a*_{IGU}|<|a*₂|.

3. The insulated glass unit of claim 1 wherein:

|b*_{IGU}|<|b*₁|; or

|b*_{IGU}|<b*₂|.

4. The insulated glass unit of claim 1 wherein b*₁ is positive and b*₂ is negative.

5. The insulated glass unit of claim 4 wherein b*₂<b*_{IGU}<b*₁.

6. The insulated glass unit of claim 5 wherein b*₁ is greater than 10.

7. The insulated glass unit of claim 5 wherein b*₂ is less than −10.

8. The insulated glass unit of claim 1 wherein
$$\sqrt{{( {a}_{IGU}^{*} )}^{2} + {( {b}_{IGU}^{*} )}^{2}} < \sqrt{{( {a}_{1}^{*} )}^{2} + {( {b}_{1}^{*} )}^{2}} ;$$
$$and$$
$$\sqrt{{( {a}_{IGU}^{*} )}^{2} + {( {b}_{IGU}^{*} )}^{2}} < \sqrt{{( {a}_{2}^{*} )}^{2} + {( {b}_{2}^{*} )}^{2}} .$$

9. The insulated glass unit of claim 1 wherein −4<b*_{IGU}<8.

10. The insulated glass unit of claim 1 wherein the photovoltaic structure is disposed on an outboard side of the IGU, and wherein the insulated glass unit further comprises a third lite disposed between the first lite and the second lite.

11. The insulated glass unit of claim 10 wherein the third lite is separated from the second lite by a second gap.

12. The insulated glass unit of claim 1 wherein the IGU is characterized by an average visible transmission (AVT) of greater than 40%.

13. The insulated glass unit of claim 1 wherein the photovoltaic structure is characterized by an average visible transmission (AVT) of greater than 50%.

14. The insulated glass unit of claim 1 wherein the photovoltaic structure is characterized by a first transmission peak at a first wavelength and the low emissivity structure is characterized by a second transmission peak at a second wavelength different from the first wavelength.

15. An insulated glass unit (IGU) comprising:
a photovoltaic structure disposed on a surface of a first lite, wherein the photovoltaic structure covers the whole surface of the first lite and is characterized by a first transmitted color (a*₁; b*₁);
a low emissivity structure disposed on a surface of a second lite, wherein the low emissivity structure is configured to transmit light characterized by a second transmitted color (a*₂; b*₂) and reflect infrared light passed through the first lite and the photovoltaic structure, wherein the first transmitted color and the second transmitted color are complementary; and wherein the low emissivity structure comprises:
a first transparent dielectric layer disposed on the surface of the second lite;
one or more metal layers disposed on the first transparent dielectric layer; and
a second transparent dielectric layer disposed on the one or more metal layers;
a third lite; and
a gap separating at least one of the first lite and the second lite or the first lite and the third lite.

16. The insulated glass unit of claim 14 wherein the photovoltaic structure is disposed on an outboard side of the IGU and the gap is filled with one or more gases, and wherein the insulated glass unit further comprises a lamination material joining the photovoltaic structure and the second lite.

17. The insulated glass unit of claim 15 wherein:
the photovoltaic structure includes a photovoltaic coating disposed on a surface of the first lite facing toward the third lite; and
the low emissivity structure includes a low emissivity coating disposed on a surface of the second lite facing toward the third lite.

18. The insulated glass unit of claim 17 further comprising a lamination material joining the photovoltaic coating and the third lite.

19. The insulated glass unit of claim 14 further comprising a first lamination material joining the photovoltaic structure and the second lite.

20. The insulated glass unit of claim 14 wherein the photovoltaic structure is characterized by a first transmission peak at a first wavelength and the low emissivity structure is characterized by a second transmission peak at a second wavelength different from the first wavelength.
